(19) United States
(12) Patent Application Publication
(10) Pub. No.: US 2026/0096442 A1
(43) Pub. Date: Apr. 2, 2026

(54) SEMICONDUCTOR PACKAGES AND METHODS OF FORMATION

(71) Applicant: Taiwan Semiconductor Manufacturing Company, Ltd., Hsinchu (TW)

(72) Inventors: Monsen LIU, Hsinchu (TW); Shuo-Mao CHEN, New Taipei City (TW); Hsien-Wei CHEN, Hsinchu City (TW); Kathy Wei YAN, Hsinchu (TW)

(21) Appl. No.: 18/903,536

(22) Filed: Oct. 1, 2024

(51) Int. Cl. H01L 23/64; H01L 21/48; H01L 23/00; H01L 23/498; H01L 25/065; H01L 25/10

(52) U.S. Cl. CPC H10W 44/601; H10W 70/05; H10W 70/65; H10W 70/685; H10W 90/00; H10W 70/60; H10W 70/655; H10W 80/312; H10W 90/722; H10W 90/794

(57) ABSTRACT

An integrated passive device (IPD) package is manufactured to include electrical connections on two or more sides of the IPD package. The IPD package may be embedded in a package core of a package substrate of a semiconductor package, which enables electrical connections to be connected to top and bottom redistribution structures of the package substrate using the conductive pads on multiple sides of the IPD package, thereby enabling the quantity and density of passive device structures included in the IPD package to be increased. The electrical connections on two or more sides of the IPD package enable the IPD package to include a plurality of IPD layers or slides of passive device components, which enables the quantity and density of passive device structures included in the IPD package to be further increased.

### BACKGROUND

A semiconductor die package may include one or more integrated circuit (IC) dies that are bonded to an interposer. Examples of IC dies include a system-on-chip (SoC) IC die, a dynamic random access memory (DRAM) IC die, a logic IC die, and/or a high bandwidth memory (HBM) IC die, among other examples. An interposer may be used to redistribute contact areas from the IC dies to a larger area of the interposer. An interposer may enable three-dimensional (3D) packaging and/or other advanced semiconductor packaging techniques.

A semiconductor package may include one or more semiconductor die packages that are bonded to a package substrate. The semiconductor die packages may be electrically interconnected through one or more redistribution structures of the package substrate. This enables the semiconductor package to include semiconductor die packages that provide different functionality, such as memory, processing, communication, and/or input/output (I/O), among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor package described herein.

FIG. 2 is a diagram of an example of a semiconductor die package described herein.

FIG. 3 is a diagram of an example of a semiconductor package described herein.

FIG. 4 is a diagram of an example of an integrated passive device (IPD) package described herein.

FIG. 5 is a diagram of an example of an IPD package described herein.

FIG. 6 is a diagram of an example of an IPD package described herein.

FIG. 7 is a diagram of an example of an IPD package described herein.

FIG. 8 is a diagram of an example of an IPD package described herein.

FIGS. 9A-9L are diagrams of an example implementation of forming a semiconductor package that includes an IPD package described herein.

FIGS. 10A-10I are diagrams of an example implementation of forming an IPD layer that may be included in an IPD package described herein.

FIGS. 11A and 11B are diagrams of an example implementation of forming an IPD package described herein.

FIGS. 12A and 12B are diagrams of an example semiconductor package described herein.

FIG. 13 is a diagram of an example semiconductor package described herein.

FIG. 14 is a flowchart of an example process associated with forming an IPD package described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a semiconductor package may include passive device structures in an off-chip package referred to as an integrated passive device (IPD) package. An IPD package may be attached to a package substrate of the semiconductor package, and may include passive device structures such as capacitors, inductors, resistors, and/or diodes, among other examples. Including passive device structures in an auxiliary package of the semiconductor package enables a greater amount of the area in the semiconductor die packages to be used for active components such as transistors and memory structures, among other examples.

An IPD package may be embedded in and/or placed on a redistribution structure of the package substrate so that electrical connections may be connected to one side of the IPD package. However, including electrical connections to only one side of the IPD package limits the input/output (I/O) density of the IPD package, which limits the quantity and density of passive device structures that may be included in the IPD package. As a result, the IPD package may offer limited capacitance, limited resistance, limited inductance, and/or limited circuit protection, among other examples.

In some implementations described herein, an IPD package is manufactured to include electrical connections on two or more sides of the IPD package. For example, an IPD package described herein may include a first plurality of conductive pads on a first side (e.g., a top side) of the IPD package and a second plurality of conductive pads on a second side (e.g., a bottom side) of the IPD package vertically opposing the first side. The IPD package may be embedded in a package core of a package substrate of a semiconductor package, which enables electrical connections to be connected to top and bottom redistribution structures of the package substrate using the conductive pads on the top side and on the bottom side of the IPD package. In this way, including electrical connections on two or more sides of the IPD package enables the I/O density of the IPD package to be increased, which enables the quantity and density of passive device structures included in the IPD package to be increased. This enables the IPD package to provide increased capacitance, increased resistance, increased inductance, and/or increased circuit protection, among other examples.

Moreover, and as described herein, the electrical connections on two or more sides of the IPD package enable the IPD package to include a plurality of IPD layers or slides of passive device components. The plurality of IPD layers of passive device components may be vertically stacked, and the quantity of IPD layers included in the IPD package may be flexibly selected.

Vertically stacking the IPD layers of passive device components enables the quantity and density of passive device structures included in the IPD package to be further increased, thereby further increasing the capacitance, resistance, inductance, and/or circuit protection provided by the IPD package.

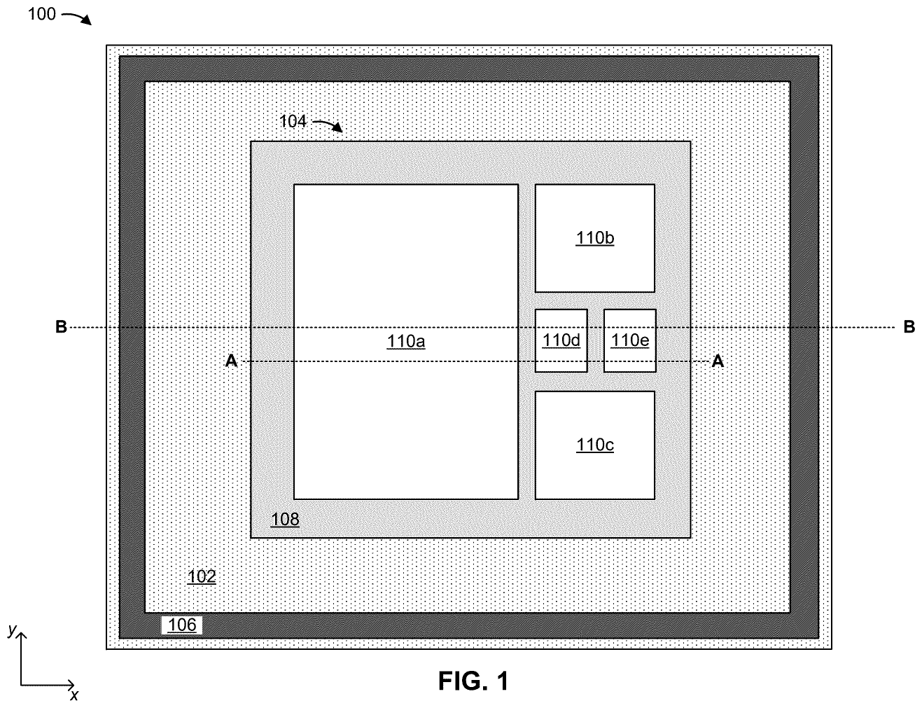

FIG. 1 is a diagram of an example semiconductor package 100 described herein. FIG. 1 illustrates a top view of the semiconductor package 100. As shown in FIG. 1, the semiconductor package 100 includes a packaged semiconductor device that includes a package substrate 102 and one or more semiconductor die packages 104 bonded, attached, mounted, and/or otherwise secured to the package substrate 102. The semiconductor package 100 may be referred to as a chip on wafer on substrate (CoWoS) package, a 3D package, a 2.5D package, and/or another type of semiconductor package.

As shown in FIG. 1, a stiffener structure 106 may be included over and/or on the package substrate 102 along the outer edges of the package substrate 102. Accordingly, the package substrate 102 may be outlined or surrounded by a stiffener structure 106. The semiconductor die package(s) 104 may be positioned within a perimeter of the stiffener structure 106 and may be spaced apart from the stiffener structure 106. The stiffener structure 106 may be included to reduce warpage and bending, and to maintain planarity of the package substrate 102. The stiffener structure 106 may include active circuitry, a non-active structure, or a combination thereof. The stiffener structure 106 may include one or more metal materials, one or more dielectric materials, and/or one or more materials of another type of material.

As further shown in FIG. 1, a semiconductor die package 104 may include an interposer 108 and one or more integrated circuit (IC) dies (e.g., an IC die 110a, an IC die 110b, an IC die 110c, an IC die 110d, and/or an IC die 110e) bonded, attached, mounted, and/or otherwise secured to the interposer 108. The quantity and arrangement of IC dies 110a-110e illustrated in FIG. 1 is an example, and other quantities and arrangements are within the scope of the present disclosure. In some implementations, a semiconductor die package 104 may include a single IC die.

As shown in FIG. 1, the one or more IC dies may be horizontally distributed (e.g., an x-direction and/or in a y-direction) on the interposer 108. In some implementations, one or more of the IC dies 110a-110e are active IC dies that include the active integrated circuits of the semiconductor die package 104 and perform the electrical and processing functions of the semiconductor die package 104. Examples of active IC dies include a logic IC die, a memory IC die, a high-bandwidth memory (HBM) IC die, an input/output (I/O) die, a system-on-chip (SoC) IC die, a dynamic random access memory (DRAM) IC die, a static random access memory (SRAM) IC die, a central processing unit (CPU) IC die, a graphics processing unit (GPU) IC die, a digital signal processing (DSP) IC die, an application specific integrated circuit (ASIC) IC die, and/or another type of active IC die. The active IC dies may be various sizes and/or shapes, and may be positioned in various locations and arrangements on the interposer 108.

In some implementations, one or more of the IC dies 110a-110e are non-active dies. Examples of non-active dies include dummy dies and/or other types of non-active dies. A dummy die may also be referred to as an insertion die, a filler die, and/or another type of die that does not perform electrical and/or processing functions of the semiconductor die package 104.

The quantity and/or position of the non-active dies in the top view of the semiconductor die package 104 (e.g., the horizontal arrangement of non-active dies in the top view) may be determined and/or selected to achieve and/or satisfy one or more parameters for semiconductor die package 104. Unused area (e.g., area that is not occupied by at least one IC die) in the horizontal arrangement of IC dies in the semiconductor die package 104 may result in reduced stiffness and/or reduced rigidity for the semiconductor die package 104. This may increase the likelihood of bending, warpage, and/or physical damage to the semiconductor die package 104. Accordingly, the quantity and/or position of the non-active dies may be determined and/or selected to reduce and/or minimize unused area in the horizontal arrangement of the IC dies in the top view. Thus, the non-active dies may be positioned in unused area between two or more active IC dies, may be positioned in unused area adjacent to (or next to) one or more active IC dies, or a combination thereof to minimize unused area in the horizontal arrangement of IC dies in the top view of the semiconductor die package 104.

As indicated above, FIG. 1 is provided as an example. Other examples may differ from what is described with regard to FIG. 1.

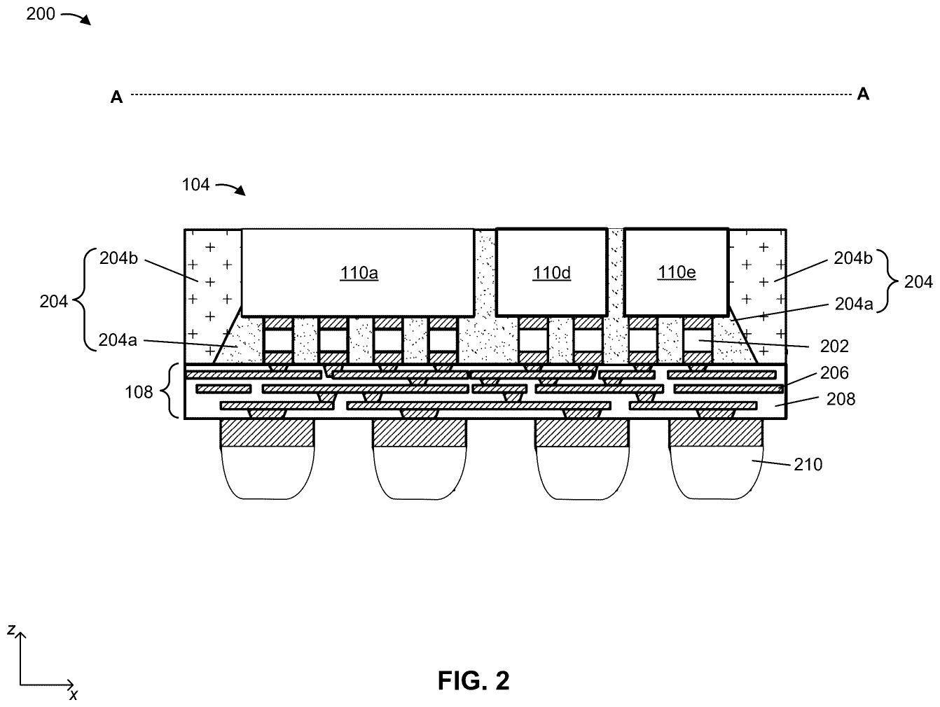

FIG. 2 is a diagram of an example 200 of a semiconductor die package 104 described herein. FIG. 2 illustrates a cross-section view of the semiconductor die package 104 along the line A-A in FIG. 1 in the x-direction in the semiconductor package 100. As shown in FIG. 2, the IC dies (e.g., the IC dies 110a, 110d, and/or 110e) may be attached to, mounted to, and/or bonded to the interposer 108 of the semiconductor die package 104. The IC dies 110b and 110c (not shown) may also be attached to, mounted to, and/or bonded to the interposer 108 in a similar manner.

The IC dies 110a-110e may be attached to the interposer 108 by a plurality of connection structures 202. The connection structures 202 may include a stud, a pillar, a bump, a solder ball, a micro-bump, an under-bump metallization (UBM) structure, and/or another type of connection structure, among other examples. The connection structures 202 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free).

The connection structures 202 may connect lands (e.g., pads) on bottom surfaces of the IC dies 110a-110e to lands on a top surface of the interposer 108. In some implementations, the connection structures 202 may include one or more electrical connections for signaling (e.g., corresponding lands of the IC dies 110a-110e and/or the interposer 108 are electrically connected to respective circuitry and/or traces of the IC dies 110a-110e and/or the interposer 108). In some implementations, the connection structures 202 may include one or more mechanical connections for attachment purposes and/or spacing purposes (e.g., corresponding lands of the IC dies 110a-110e and/or the interposer 108 are not electrically connected to respective circuitry and/or traces of the IC dies 110a-110e and/or the interposer 108). In some implementations, one or more of the connection structures 202 may function both electrically and mechanically.

As further shown in FIG. 2, one or more types of filler materials 204 may be included above the interposer 108 and in areas surrounding the IC dies 110a-110e and/or the connection structures 202. For example, an underfill material 204a may be included between the connection structures 202 under the IC dies 110a-110e. As another example, an encapsulant material (also referred to as a molding compound) 204b may be included over and/or on the interposer 108 and/or over and/or on portions of the underfill material 204a around the perimeter of the semiconductor die package 104.

The underfill material 204a may include a polymer, one or more fillers dispersed in a resin, an epoxy-based resin, and/or another type of insulating material. In some implementations, the underfill material 204a fills in the gaps between the IC dies 110a-110e. In some implementations, the underfill material 204a may fully fill the gaps approximately up to a top surface of the IC dies 110a-110e. The underfill material 204a may extend outward from one or more of the IC dies 110a-110e toward the perimeter of the semiconductor die package 104. For example, the underfill material 204a may extend outward in a tapered or sloped manner. As another example, underfill material 204a may extend outward in a concave manner or in a convex manner.

The encapsulant material 204b may include a polymer, one or more fillers dispersed in a resin, an epoxy-based resin, and/or another type of insulating material. In some implementations, the encapsulant material 204b may fully surround the top surfaces of the IC dies 110a-110e such that the encapsulant material 204b protects the IC dies 110a-110e in the semiconductor die package 104.

In some implementations, the interposer 108 includes a redistribution structure (or redistribution layer (RDL)). In these implementations, the interposer 108 includes a plurality of conductive traces 206 (e.g., copper (Cu) traces) in a base layer 208 formed of a polymer material, a molding material, and/or a dielectric material (e.g., silicon oxide (SiOₓ such as SiO₂), undoped silicate glass (USG)). In some implementations, the interposer 108 includes a silicon interposer. In these implementations, the interposer 108 includes a plurality of conductive traces 206 (e.g., copper (Cu) traces) in a base layer 208 that is formed of silicon (Si).

The interposer 108 may be configured to distribute electrical signals between the connection structures 202 and connection structures 210 on opposing sides of the interposer 108. The conductive traces 206 and the connection structures 210 may include one or more materials such as a gold (Au) material, a copper (Cu) material, a silver (Ag) material, a nickel (Ni) material, a tin (Sn) material, or a palladium (Pd) material, among other examples. In some implementations, the conductive traces 206 includes one or more conductive vertical access connection structures (vias) that connect one or more metallization layers of the conductive traces 206.

As indicated above, FIG. 2 is provided as an example. Other examples may differ from what is described with regard to FIG. 2.

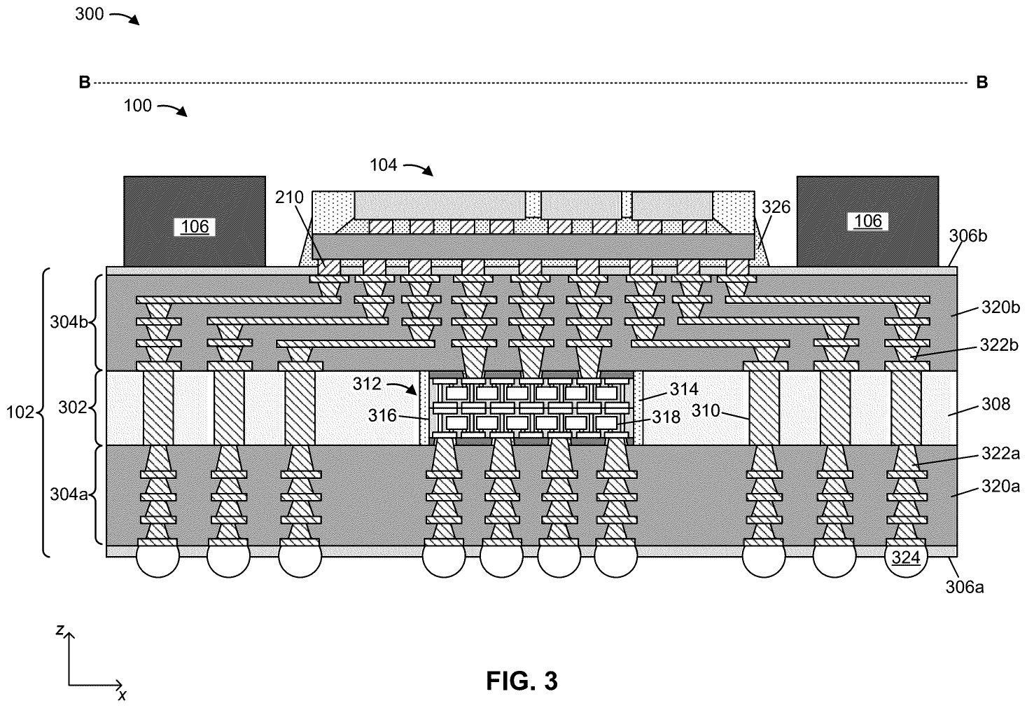

FIG. 3 is a diagram of an example 300 of a semiconductor package 100 described herein. FIG. 3 illustrates a cross-section view of the semiconductor package 100 along the line B-B in the x-direction in FIG. 1.

As shown in FIG. 3, the package substrate 102 of the semiconductor package 100 may include a substrate core 302 that is sandwiched between a first redistribution structure 304a (e.g., a bottom RDL) and a second redistribution structure 304b (e.g., a top RDL). Thus, the package substrate 102 may include a vertically arranged (e.g., in the z-direction) stack that includes the first redistribution structure 304a, the substrate core 302, and the second redistribution structure 304b.

A passivation layer 306a may be included on the bottom of the first redistribution structure 304a, and a passivation layer 306b may be included on the top of the second redistribution structure 304b. The passivation layers 306a and 306b may include one or more dielectric materials, such as a silicon oxide (SiOₓ), a silicon nitride (SiₓN_{y}), a silicon carbide (SiCₓ), a silicon carbon nitride (SiCN), and/or a silicon oxynitride (SiON), among other examples.

The substrate core 302 may include substrate layer 308 and one or more interconnect structures 310 extending through the substrate layer 308. The substrate layer 308 may include a silicon (Si) substrate, a dielectric substrate, a polymer substrate, and/or another suitable substrate material. The interconnect structures 310 may include through hole vias (THVs), through integrated fanout vias (TIVs), through silicon vias (TSVs), and/or another type of interconnect structures. The interconnect structures 310 may enable signals and/or power to be distributed between the first redistribution structure 304a and the second redistribution structure 304b.

As further shown in FIG. 3, a recess 312 may be included in the substrate layer 308 of the substrate core 302. The recess 312 may be filled with a filler material 314, and an in IPD package 316 may be included within the recess 312. The filler material 314 may fill in the remaining area within the recess 312 that is not occupied by the IPD package 316. In this way, the IPD package 316 is embedded in the substrate core 302 and is included vertically (e.g., in the z-direction) between the first redistribution structure 304a and the second redistribution structure 304b in the package substrate 102. One or more of the interconnect structures 310 that extend through the substrate layer 308 of the substrate core 302 may extend alongside the IPD package 316.

The IPD package 316 includes a plurality of vertically-arranged layers (or slices) of passive device structures 318. The plurality of layers of passive device structures 318 may be stacked and vertically arranged in the z-direction in the IPD package 316. Including the plurality of layers of passive device structures 318 in the IPD package 316, as opposed to only a single layer of passive device structures 318, enables a greater density of passive device structures 318 to be included in the IPD package 316 without increasing (or with minimal increase in) the lateral size of the IPD package 316. The passive device structures 318 may include one or more types of passive IC devices, such as capacitors, resistors, diodes, transformers, waveguides, and/or inductors, among other examples.

As further shown in FIG. 3, the first redistribution structure 304a may include an insulator layer 320a and a plurality of conductive structures 322a included in the insulator layer. The insulator layer 320a may include polyimide, polybenzoxazole (PBO), benzocyclobutene (BCB), an ajinomoto buildup film (ABF), a solder resist (SR) film, a pre-impregnated composite fiber (prepreg), a non-woven glass fabric, and/or another suitable insulator material. The conductive structures 322a may include one or more electrically conductive materials, such as copper (Cu), aluminum (Al), tungsten (W), cobalt (Co), ruthenium (Ru), tin (Sn), nickel (Ni), and/or another suitable electrically conductive material.

The conductive structures 322a of the first redistribution structure 304a may be arranged in a plurality of vertically stacked layers in the z-direction. The layers of conductive structures 322a may extend between a top side of the first redistribution structure 304a facing the substrate core 302 and a second side of the first redistribution structure 304a facing the bottom of the semiconductor package 100. The layers of conductive structures 322a may be interconnected to provide a signal and/or power path between the interconnect structures 310 and package connection structures 324 located on the bottom side of the first redistribution structure 304a. The layers of conductive structures 322a may also provide a signal and/or power path between the interconnect structures 310 and the IPD package 316, and/or between the package connection structures 324 and the IPD package 316. The package connection structures 324 may include ball grid array (BGA) balls, land grid array (LGA) pads, pin grid array (PGA) pins, and/or another type of connection structures that enable the semiconductor package 100 to be attached (e.g., soldered, bonded, socketed) to another device or layer.

As further shown in FIG. 3, the second redistribution structure 304b may similarly include an insulator layer 320b and a plurality of layers of conductive structures 322b included in the insulator layer 320b. The layers of conductive structures 322b may extend between a top side of the second redistribution structure 304b facing the semiconductor die package(s) 104 and a second side of the second redistribution structure 304b facing the substrate core 302. The layers of conductive structures 322b may be interconnected to provide a signal and/or power path between the interconnect structures 310 and the semiconductor die package(s) 104. The layers of conductive structures 322b may also provide a signal and/or power path between the interconnect structures 310 and the IPD package 316, and/or between the semiconductor die package(s) 104 and the IPD package 316.

As further shown in FIG. 3, the IPD package 316 is a doubled-sided package in that connections to the IPD package 316 are included on the top side of the IPD package 316 facing the second redistribution structure 304b and on the bottom side of the IPD package 316 facing the first redistribution structure 304a. For example, the IPD package 316 may be physically connected and/or electrically connected to one or more conductive structures 322a in the first redistribution structure 304a at the bottom of the IPD package 316, and the IPD package 316 may be physically connected and/or electrically connected to one or more conductive structures 322b in the second redistribution structure 304b at the top of the IPD package 316.

In some implementations, the connections to the conductive structures 322a at the bottom of the IPD package 316 may be used to electrically connect the passive device structures 318 of the IPD package 316 to electrical ground (e.g., through the package connection structures 324). In some implementations, the connections to the conductive structures 322b at the top of the IPD package 316 may be used to electrically connect the passive device structures 318 of the IPD package 316 to power or signal connections from the semiconductor die package(s) 104. In some implementations, the connections at the bottom of the IPD package 316 may include a combination of electrical ground connections and signal/power connections, and/or the connections at the top of the IPD package 316 may include a combination of electrical ground connections and signal/power connections.

Including connections on both the top side and on the bottom side of the IPD package 316 increases the connection density (e.g., the I/O density) of the IPD package 316, which enables the IPD package 316 to include a greater quantity and/or a greater density of passive device structures 318 than if connections to the IPD package 316 were on only the top side or only the bottom side of the IPD package 316.

As further shown in FIG. 3, the semiconductor die package(s) 104 may be attached to the top of the second redistribution structure 304b of the package substrate 102. The connection structures 210 of the semiconductor die package(s) 104 may be physically connected and/or electrically connected with an upper layer of conductive structures 322b included in the second redistribution structure 304b. The stiffener structure 106 may be attached to the top surface of the second redistribution structure 304b by an adhesive layer (e.g., an epoxy, an organic adhesive) (not shown). Another underfill material 326 may be included under the semiconductor die package(s) 104 and in between the connection structures 210.

As indicated above, FIG. 3 is provided as an example. Other examples may differ from what is described with regard to FIG. 3.

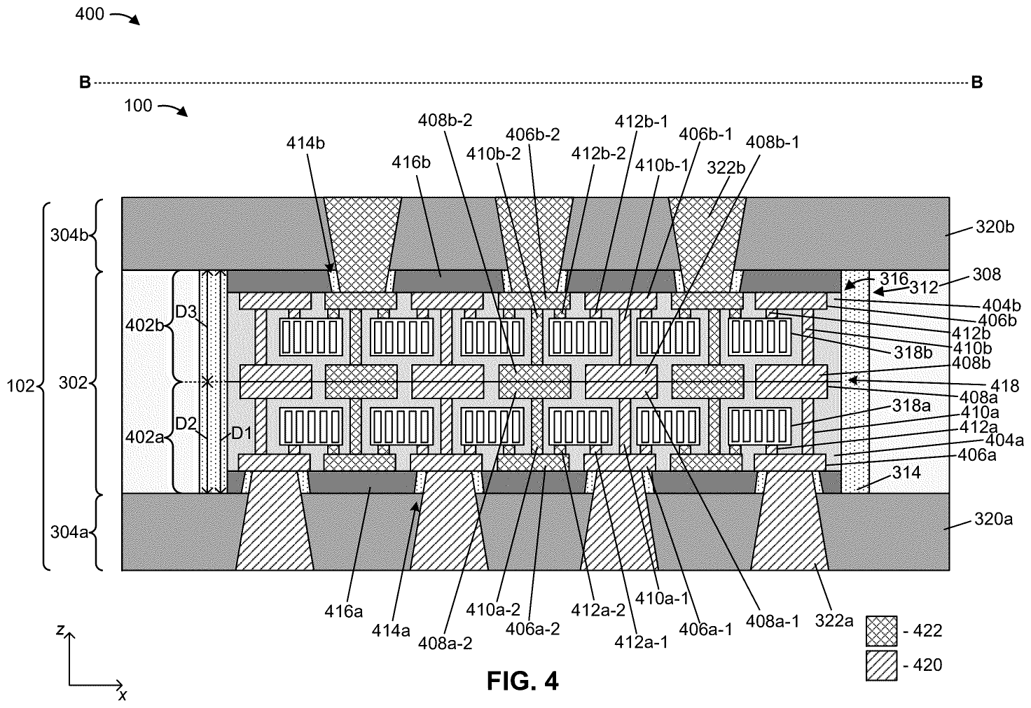

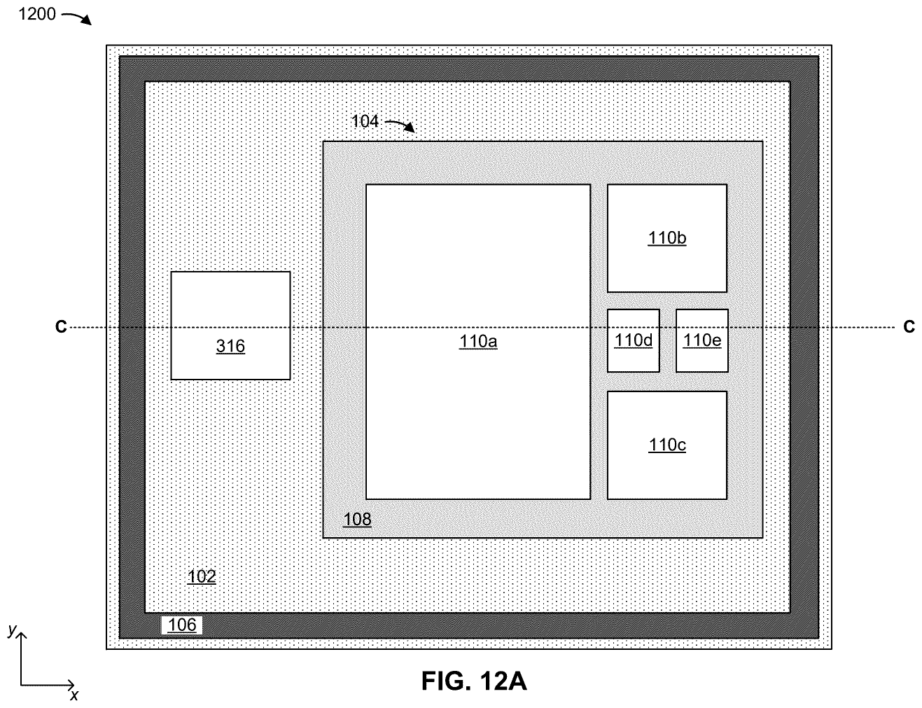

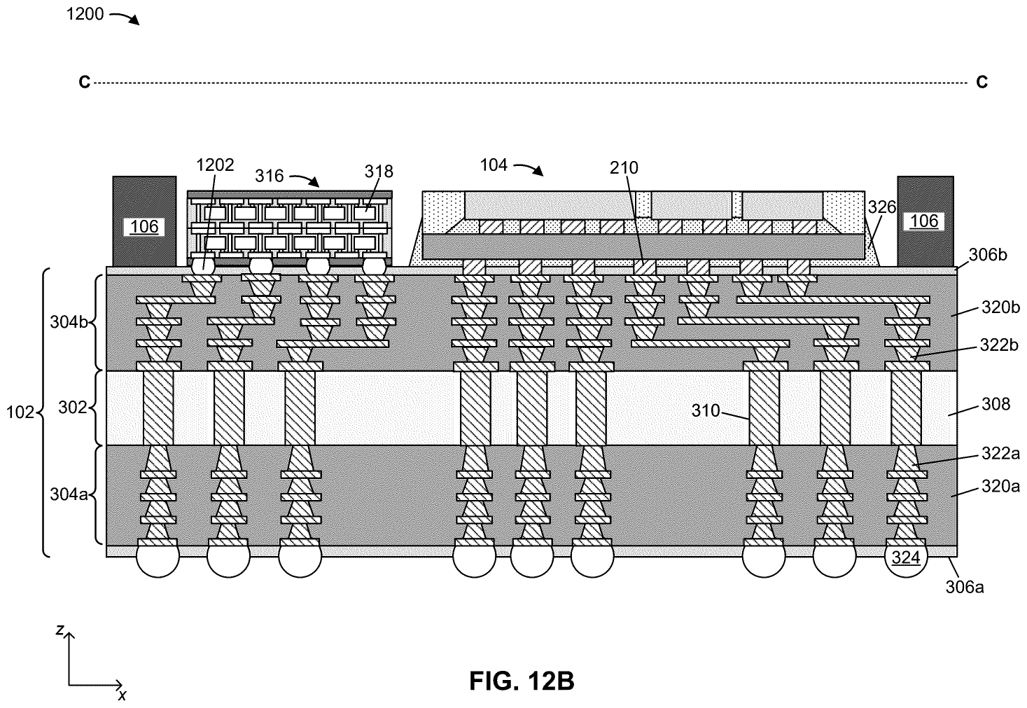

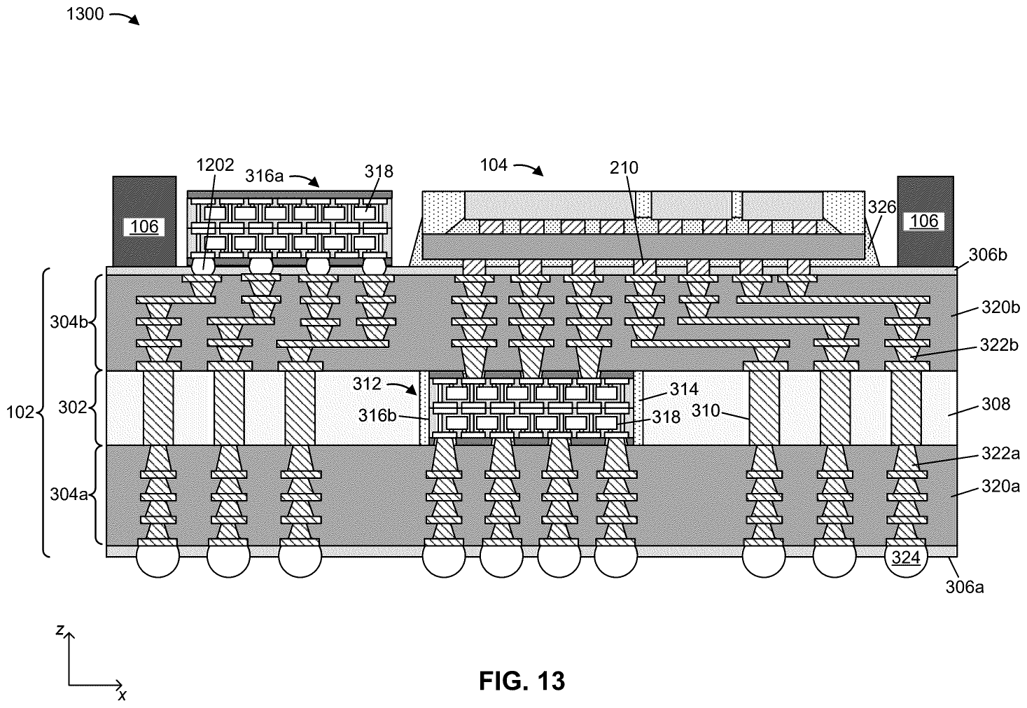

FIG. 4 is a diagram of an example 400 of an IPD package 316 described herein. The example 400 of the IPD package 316 may be included in the semiconductor package 100. For example, the example 400 of the IPD package 316 may be embedded in the substrate core 302 of the package substrate 102 of the semiconductor package 100, as illustrated in the example in FIG. 3 and/or in an example in FIG. 13. As another example, the example 400 of the IPD package 316 may be included on the first redistribution structure 304a and/or on the second redistribution structure 304b, as shown in an example in FIG. 12 and/or in the example in FIG. 13.

As shown in FIG. 4, the IPD package 316 includes a plurality of layers of passive device structures 318. For example, the IPD package 316 may include a first IPD layer 402a (or a first IPD slice) that includes a first plurality of laterally-arranged passive device structures 318a, and a second IPD layer 402b (or a second IPD slice) on the first IPD layer 402a that includes a second plurality of laterally-arranged passive device structures 318b. The first IPD layer 402a and the second IPD layer 402b may be stacked and vertically arranged (in the z-direction) in the IPD package 316 such that the passive device structures 318a are vertically arranged with the passive device structures 318b in the IPD package 316. In some implementations, the IPD package 316 includes additional IPD layers that are arranged in a similar manner.

The IPD package 316 may have a z-direction height (indicated in FIG. 4 as dimension D1) that is included in a range of approximately 700 microns to approximately 2100 microns. However, other values and ranges for the z-direction height of the IPD package 316 are within the scope of the present disclosure. The first IPD layer 402a may have a z-direction height (indicated in FIG. 4 as dimension D2) that is included in a range of approximately 1 micron to approximately 700 microns. However, other values and ranges for the z-direction height of the first IPD layer 402a are within the scope of the present disclosure. The second IPD layer 402b may have a z-direction height (indicated in FIG. 4 as dimension D3) that is included in a range of approximately 1 micron to approximately 700 microns. However, other values and ranges for the z-direction height of the second IPD layer 402b are within the scope of the present disclosure. In some implementations, a ratio of the z-direction height of the first IPD layer 402a to the z-direction height of the second IPD layer 402b is included in a range of approximately 1:10 to approximately 10:1. However, other values and ranges are within the scope of the present disclosure.

As further shown in FIG. 4, the first IPD layer 402a and the second IPD layer 402b may respectively include a substrate layer 404a and a substrate layer 404b. The substrate layers 404a and 404b may each include a semiconductor layer (e.g., a silicon (Si) substrate), a dielectric substrate, a polymer substrate, and/or another suitable substrate material. The passive device structures 318a of the first IPD layer 402a may be included in the substrate layer 404a, and the passive device structures 318b of the second IPD layer 402b may be included in the substrate layer 404b.

The first IPD layer 402a may further include a plurality of conductive pads 406a on a first side of the substrate layer 404a, and a plurality of conductive pads 408a on a second side of the substrate layer 404a opposing the first side. The passive device structures 318a may be located vertically between (e.g., in the z-direction) the conductive pads 406a and the conductive pads 408a in the substrate layer 404a.

The first IPD layer 402a may further include plurality of interconnect structures 410a that extend through the substrate layer 404a between the conductive pads 406a and the conductive pads 408a. First ends of the interconnect structures 410a may be coupled (e.g., physically and/or electrically) to the conductive pads 406a, and second (opposing) ends of the interconnect structures 410a may be coupled (e.g., physically and/or electrically) to the conductive pads 408a. Thus, the interconnect structures 410a may electrically connect the conductive pads 406a to the conductive pads 408a. The interconnect structures 410a may extend alongside the passive device structures 318a in the substrate layer 404a. The first IPD layer 402a may further include a plurality of contacts 412a that electrically connect the passive device structures 318a to the conductive pads 406a.

The second IPD layer 402b may include a similar combination and arrangement of layers and/or structures as the first IPD layer 402a. For example, the second IPD layer 402b may further include a plurality of conductive pads 406b on a first side of the substrate layer 404b, and a plurality of conductive pads 408b on a second side of the substrate layer 404b opposing the first side. The passive device structures 318b may be located vertically between (e.g., in the z-direction) the conductive pads 406b and the conductive pads 408b in the substrate layer 404b.

As another example, second IPD layer 402b may further include plurality of interconnect structures 410b that extend through the substrate layer 404b between the conductive pads 406b and the conductive pads 408b. First ends of the interconnect structures 410b may be coupled (e.g., physically and/or electrically) to the conductive pads 406b, and second (opposing) ends of the interconnect structures 410b may be coupled (e.g., physically and/or electrically) to the conductive pads 408b. Thus, the interconnect structures 410b may electrically connect the conductive pads 406b to the conductive pads 408b. The interconnect structures 410b may extend alongside the passive device structures 318b in the substrate layer 404b. As another example, the second IPD layer 402b may further include a plurality of contacts 412b that electrically connect the passive device structures 318b to the conductive pads 406b.

As further shown in FIG. 4, the second IPD layer 402b is stacked on the first IPD layer 402a in a vertically mirrored orientation relative to the orientation of the first IPD layer 402a. In this way, the conductive pads 406a and 406b are facing away from each other, and the conductive pads 408a and 408b are facing each other. Moreover, the passive device structures 318a of the first IPD layer 402a and the passive device structures 318b of the second IPD layer 402b are connected to conductive pads on vertically opposing sides of the IPD package 316. For example, the passive device structures 318a of the first IPD layer 402a are connected to the conductive pads 406a through the contacts 412a at the bottom of the first IPD layer 402a (which corresponds to the bottom of the IPD package 316), and the passive device structures 318b of the second IPD layer 402b are connected to the conductive pads 406b through the contacts 412b at the top of the second IPD layer 402b (which corresponds to the top of the IPD package 316).

The conductive pads 406a, 406b, 408a, and 408b may each include metal pads and/or another type of conductive structure that are elongated in the x-direction and/or in the y-direction. The conductive pads 406a, 406b, 408a, and 408b may each include one or more metal materials such as tungsten (W), cobalt (Co), titanium (Ti), copper (Cu), gold (Au), silver (Ag), molybdenum (Mo), ruthenium (Ru), a metal alloy, and/or another metal. The interconnect structures 310a and 310b may each include vias, TSVs, TIVs, THVs, and/or another type of conductive structures that are elongated in the z-direction. The interconnect structures 310a and 310b may each include one or more metal materials such as tungsten (W), cobalt (Co), titanium (Ti), copper (Cu), gold (Au), silver (Ag), molybdenum (Mo), ruthenium (Ru), a metal alloy, and/or another metal.

As further shown in FIG. 4, at least a first subset of the conductive pads 406a (e.g., conductive pads 406a-1) of the first IPD layer 402a may be physically connected and/or electrically connected to conductive structures 322a in the first redistribution structure 304a of the package substrate 102. The conductive pads 406a-1 may also be physically connected and/or electrically connected to a first subset of the interconnect structures 410a (e.g., interconnect structures 410a-1) and to a first subset of the contacts 412a (e.g., contacts 412a-1). In the example 400 of the IPD package 316, a second subset of conductive pads 406a (e.g., conductive pads 406a-2) are not directly connected to conductive structures 322a in the first redistribution structure 304a, and instead are physically connected and/or electrically connected to a second subset of the interconnect structures 410a (e.g., interconnect structures 410a-2) and to a second subset of the contacts 412a (e.g., contacts 412a-2).

At least a first subset of the conductive pads 406b (e.g., conductive pads 406b-1) are not directly connected to conductive structures 322b in the second redistribution structure 304b, and instead are physically connected and/or electrically connected to a first subset of the interconnect structures 410b (e.g., interconnect structures 410b-1) and to a first subset of the contacts 412b (e.g., contacts 412b-1). In the example 400 of the IPD package 316, a second subset of conductive pads 406b (e.g., conductive pads 406b-2) of the second IPD layer 402b may be physically connected and/or electrically connected to conductive structures 322b in the second redistribution structure 304b of the package substrate 102. The conductive pads 406b-2 may also be physically connected and/or electrically connected to a second subset of the interconnect structures 410b (e.g., interconnect structures 410b-2) and to a second subset of the contacts 412b (e.g., contacts 412b-2).

Thus, the bottom side of the IPD package 316 is physically connected and/or electrically connected to conductive structures 322a in the first redistribution structure 304a and the top side of the IPD package 316 is physically connected and/or electrically connected to conductive structures 322b in the second redistribution structure 304b. The conductive structures 322a may extend through recesses 414a in a passivation layer 416a on the first IPD layer 402a, and the conductive structures 322b may extend through recesses 414b in a passivation layer 416b on the second IPD layer 402b.

At a bonding interface 418 between the first IPD layer 402a and the second IPD layer 402b, the conductive pads 408a and the conductive pads 408b may be bonded together in metal-to-metal bonds. In some implementations, bonding dielectric layers (not shown) are included between the substrate layers 404a and 404b, and the bonding dielectric layers are bonded together in dielectric-to-dielectric bonds at the bonding interface 418.

The bonds between the conductive pads 408a and the conductive pads 408b enable grounding paths 420 and signal/power paths 422 to be formed between the first IPD layer 402a and the second IPD layer 402b. A grounding path 420 for a passive device structure 318a in the first IPD layer 402a may include a contact 412a-1, a conductive pad 406a-1, and a conductive structure 322a. A grounding path 420 for a passive device structure 318b in the second IPD layer 402b may include a contact 412b-1, a conductive pad 406b-1, an interconnect structure 410b-1, a conductive pad 408b-1, a conductive pad 408a-1, an interconnect structure 410a-1, a conductive pad 406a-1, and a conductive structure 322a.

A signal/power path 422 for a passive device structure 318a in the first IPD layer 402a may include a contact 412a-2, a conductive pad 406a-2, an interconnect structure 410a-2, a conductive pad 408a-2, a conductive pad 408b-2, an interconnect structure 410b-2, a conductive pad 406b-2, and a conductive structure 322b. A signal/power path 422 for a passive device structure 318b in the second IPD layer 402b may include a contact 412b-2, a conductive pad 406b-2, and a conductive structure 322b.

As further shown in FIG. 4, contacts 412a-1 (e.g., grounding contacts) of two or more passive device structures 318a in the first IPD layer 402a may be directly connected to the same contact structure 406a-1, and/or contacts 412a-2 (e.g., signal/power contacts) of two or more passive device structures 318a in the first IPD layer 402a may be directly connected to the same contact structure 406a-2. Thus, a contact 412a-1 and a contact 412a-2 of a passive device structure 318a may be directly connected to different conductive structures (e.g., a conductive structure 406a-1 and a conductive structure 406a-2, respectively).

Similarly, contacts 412b-1 (e.g., grounding contacts) of two or more passive device structures 318b in the second IPD layer 402b may be directly connected to the same contact structure 406b-1, and/or contacts 412b-2 (e.g., signal/power contacts) of two or more passive device structures 318b in the second IPD layer 402b may be directly connected to the same contact structure 406b-2. Thus, a contact 412b-1 and a contact 412b-2 of a passive device structure 318b may be directly connected to different conductive structures (e.g., a conductive structure 406b-1 and a conductive structure 406b-2, respectively).

As indicated above, FIG. 4 is provided as an example. Other examples may differ from what is described with regard to FIG. 4.

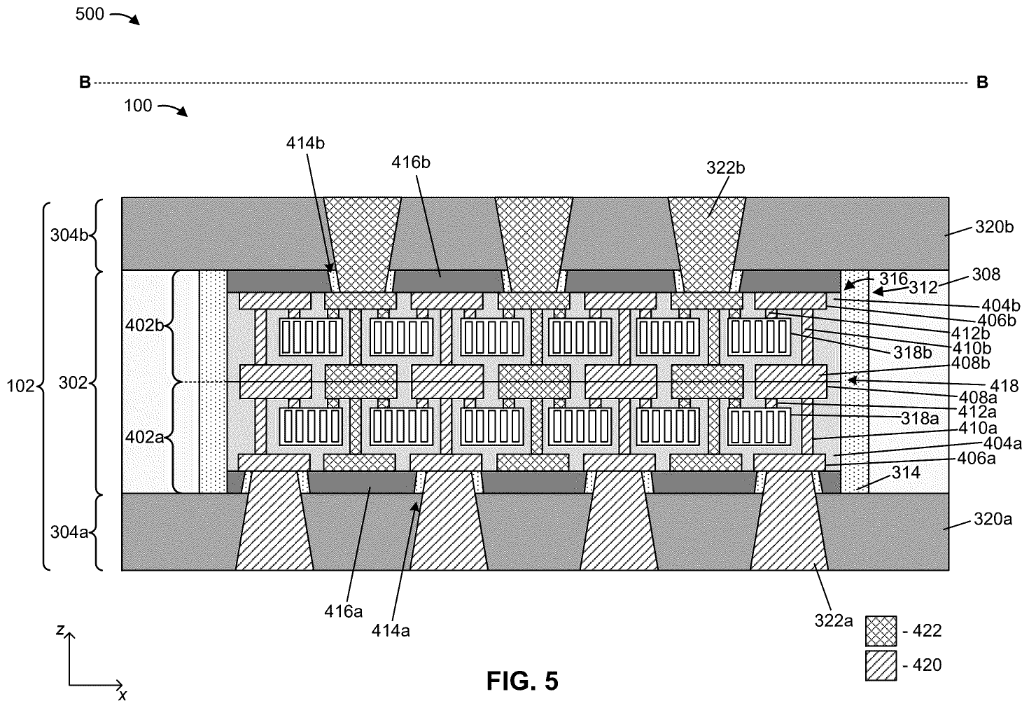

FIG. 5 is a diagram of an example 500 of an IPD package 316 described herein. The example 500 of the IPD package 316 may be included in the semiconductor package 100. For example, the example 500 of the IPD package 316 may be embedded in the substrate core 302 of the package substrate 102 of the semiconductor package 100, as illustrated in the example in FIG. 3 and/or in the example in FIG. 13. As another example, the example 500 of the IPD package 316 may be included on the first redistribution structure 304a and/or on the second redistribution structure 304b, as shown in the example in FIG. 12 and/or in the example in FIG. 13.

As shown in FIG. 5, the example 500 of the IPD package 316 includes a similar combination and arrangement of layers and/or structures as the example 400 of the IPD package 316 illustrated in FIG. 4. However, in the example 500, the passive device structures 318a of the first IPD layer 402a of the IPD package 316 are connected to the conductive pads 408a at the bonding interface 418 between the first IPD layer 402a and the second IPD layer 402b through the contacts 412a. Thus, the passive device structures 318a and the contacts 412a are connected to an opposing side of the first IPD layer 402a in the example 500 relative to the passive device structures 318a and the contacts 412a in the first IPD layer 402a in the example 400 of the IPD package 316 in FIG. 4.

As indicated above, FIG. 5 is provided as an example. Other examples may differ from what is described with regard to FIG. 5.

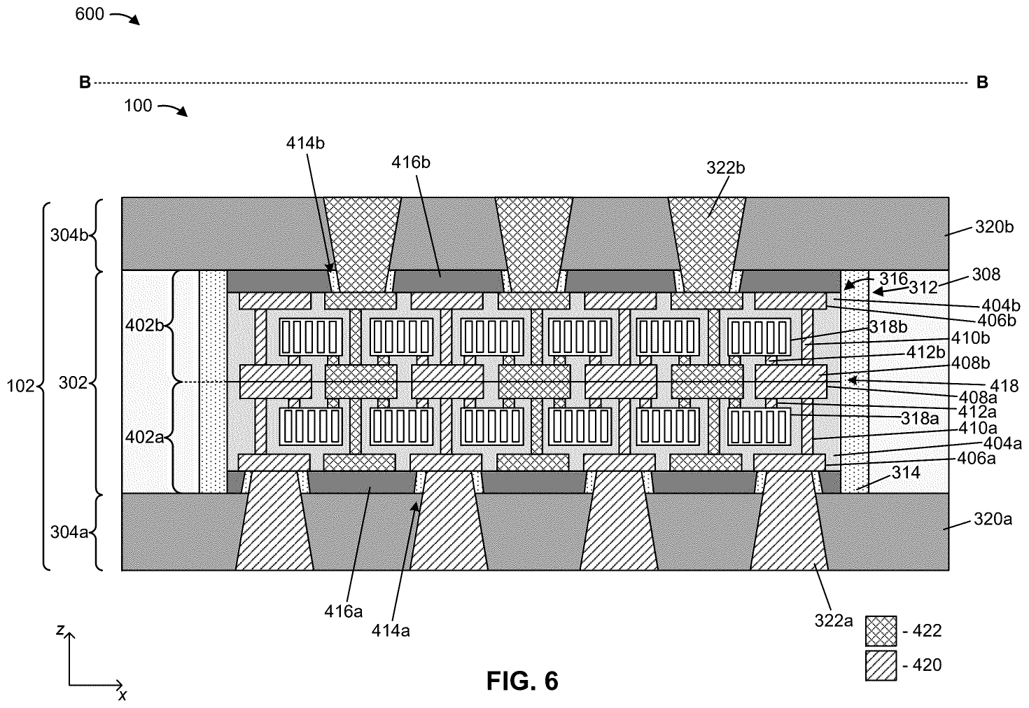

FIG. 6 is a diagram of an example 600 of an IPD package 316 described herein. The example 600 of the IPD package 316 may be included in the semiconductor package 100. For example, the example 600 of the IPD package 316 may be embedded in the substrate core 302 of the package substrate 102 of the semiconductor package 100, as illustrated in the example in FIG. 3 and/or in the example in FIG. 13. As another example, the example 600 of the IPD package 316 may be included on the first redistribution structure 304a and/or on the second redistribution structure 304b, as shown in the example in FIG. 12 and/or in the example in FIG. 13.

As shown in FIG. 6, the example 600 of the IPD package 316 includes a similar combination and arrangement of layers and/or structures as the example 400 of the IPD package 316 illustrated in FIG. 4. However, in the example 600, the passive device structures 318a of the first IPD layer 402a of the IPD package 316 are connected to the conductive pads 408a at the bonding interface 418 between the first IPD layer 402a and the second IPD layer 402b through the contacts 412a. Thus, the passive device structures 318a and the contacts 412a are connected to an opposing side of the first IPD layer 402a in the example 600 relative to the passive device structures 318a and the contacts 412a in the first IPD layer 402a in the example 400 of the IPD package 316 in FIG. 4.

Similarly, in the example 600, the passive device structures 318b of the second IPD layer 402b of the IPD package 316 are connected to the conductive pads 408b at the bonding interface 418 between the first IPD layer 402a and the second IPD layer 402b through the contacts 412b. Thus, the passive device structures 318b and the contacts 412b are connected to an opposing side of the second IPD layer 402b in the example 600 relative to the passive device structures 318b and the contacts 412b in the second IPD layer 402b in the example 400 of the IPD package 316 in FIG. 4. In this way, the passive device structures 318a and 318b are facing each other at the bonding interface 418 in the IPD package 316.

As indicated above, FIG. 6 is provided as an example. Other examples may differ from what is described with regard to FIG. 6.

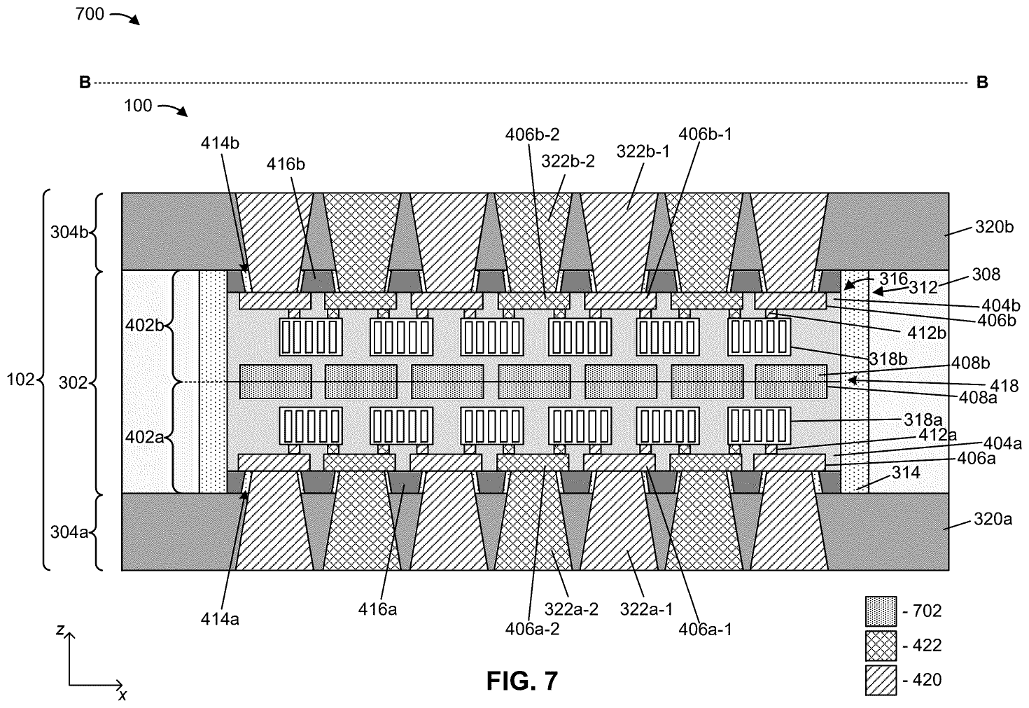

FIG. 7 is a diagram of an example 700 of an IPD package 316 described herein. The example 700 of the IPD package 316 may be included in the semiconductor package 100. For example, the example 700 of the IPD package 316 may be embedded in the substrate core 302 of the package substrate 102 of the semiconductor package 100, as illustrated in the example in FIG. 3 and/or in the example in FIG. 13. As another example, the example 700 of the IPD package 316 may be included on the first redistribution structure 304a and/or on the second redistribution structure 304b, as shown in the example in FIG. 12 and/or in the example in FIG. 13.

As shown in FIG. 7, the example 700 of the IPD package 316 includes a similar combination and arrangement of layers and/or structures as the example 400 of the IPD package 316 illustrated in FIG. 4. However, in the example 700, the interconnect structures 410a and 410b are omitted from the first IPD layer 402a and the second IPD layer 402b. Instead, a first subset of the conductive pads 406a (e.g., the conductive pads 406a-1) are physically connected and/or electrically connected to a first subset of conductive structures 322a (e.g., conductive structures 322a-1), and a second subset of the conductive pads 406a (e.g., the conductive pads 406a-2) are physically connected and/or electrically connected to a first subset of conductive structures 322a (e.g., conductive structures 322a-2). The conductive pads 406a-1 and the conductive structures 322a-1 provide grounding paths for the passive device structures 318a in the first IPD layer 402a, and the conductive pads 406a-2 and the conductive structures 322a-2 provide signal/power paths for the passive device structures 318a in the first IPD layer 402a.

Similarly, a first subset of the conductive pads 406b (e.g., the conductive pads 406b-1) are physically connected and/or electrically connected to a first subset of conductive structures 322b (e.g., conductive structures 322b-1), and a second subset of the conductive pads 406b (e.g., the conductive pads 406b-2) are physically connected and/or electrically connected to a first subset of conductive structures 322b (e.g., conductive structures 322b-2). The conductive pads 406b-1 and the conductive structures 322b-1 provide grounding paths for the passive device structures 318b in the second IPD layer 402b, and the conductive pads 406b-2 and the conductive structures 322b-2 provide signal/power paths for the passive device structures 318b in the second IPD layer 402b.

As further shown in FIG. 7, the conductive pads 408a are not electrically connected to (e.g., are electrically isolated from) the conductive pads 406a in the first IPD layer 402a, and the conductive pads 408b are not electrically connected to (e.g., are electrically isolated from) the conductive pads 406b in the second IPD layer 402b. The conductive pads 408a and 408b are included as dummy pads 702 that are used to form the metal-to-metal bonds between the first IPD layer 402a and the second IPD layer 402b at the bonding interface 418.

As indicated above, FIG. 7 is provided as an example. Other examples may differ from what is described with regard to FIG. 7.

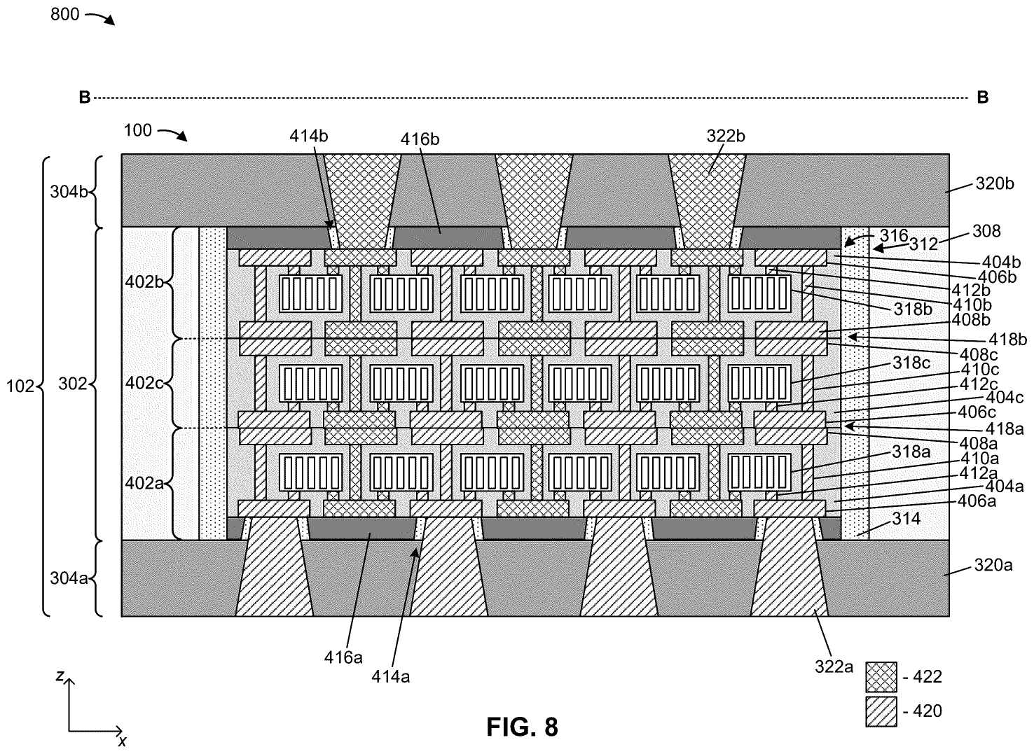

FIG. 8 is a diagram of an example 800 of an IPD package 316 described herein. The example 800 of the IPD package 316 may be included in the semiconductor package 100. For example, the example 800 of the IPD package 316 may be embedded in the substrate core 302 of the package substrate 102 of the semiconductor package 100, as illustrated in the example in FIG. 3 and/or in the example in FIG. 13. As another example, the example 800 of the IPD package 316 may be included on the first redistribution structure 304a and/or on the second redistribution structure 304b, as shown in the example in FIG. 12 and/or in the example in FIG. 13.

As shown in FIG. 8, the example 800 of the IPD package 316 includes a similar combination and arrangement of layers and/or structures as the example 400 of the IPD package 316 illustrated in FIG. 4. However, in the example 800, the IPD package 316 includes a third IPD layer 402c vertically between the first IPD layer 402a and the second IPD layer 402b.

The third IPD layer 402c may include a similar combination and arrangement of layers and/or structures as the first IPD layer 402a and/or the second IPD layer 402b. For example, the third IPD layer 402c may further include a plurality of conductive pads 406c on a first side of a substrate layer 404c, and a plurality of conductive pads 408c on a second side of the substrate layer 404c opposing the first side. The third IPD layer 402c may include a plurality of passive device structures 318c that may be located vertically between (e.g., in the z-direction) the conductive pads 406c and the conductive pads 408c in the substrate layer 404c. In this way, the passive device structures 318a, the passive device structures 318b, and the passive device structures 318c are vertically arranged in the z-direction in the IPD package 316.

As another example, third IPD layer 402c may further include plurality of interconnect structures 410c that extend through the substrate layer 404c between the conductive pads 406c and the conductive pads 408c. First ends of the interconnect structures 410c may be coupled (e.g., physically and/or electrically) to the conductive pads 406c, and second (opposing) ends of the interconnect structures 410c may be coupled (e.g., physically and/or electrically) to the conductive pads 408c. Thus, the interconnect structures 410c may electrically connect the conductive pads 406c to the conductive pads 408c. The interconnect structures 410c may extend alongside the passive device structures 318c in the substrate layer 404c.

In the example 800, the third IPD layer 402c further includes a plurality of contacts 412c that electrically connect the passive device structures 318c to the conductive pads 406c. Additionally and/or alternatively, contacts 412c may electrically connect one or more of the passive device structures 318c to the conductive pads 408c in the third IPD layer 402c.

At a bonding interface 418a between the first IPD layer 402a and the third IPD layer 402c, the conductive pads 408a and the conductive pads 406c may be bonded together in metal-to-metal bonds. In some implementations, bonding dielectric layers (not shown) are included between the substrate layers 404a and 404c, and the bonding dielectric layers are bonded together in dielectric-to-dielectric bonds at the bonding interface 418a.

At a bonding interface 418b between the second IPD layer 402b and the third IPD layer 402c, the conductive pads 408b and the conductive pads 408c may be bonded together in metal-to-metal bonds. In some implementations, bonding dielectric layers (not shown) are included between the substrate layers 404b and 404c, and the bonding dielectric layers are bonded together in dielectric-to-dielectric bonds at the bonding interface 418b.

As indicated above, FIG. 8 is provided as an example. Other examples may differ from what is described with regard to FIG. 8. Moreover, other examples of IPD packages 316 illustrated and described herein may include another quantity of IPD layers (e.g., greater than two IPD layers, greater than 3 IPD layers).

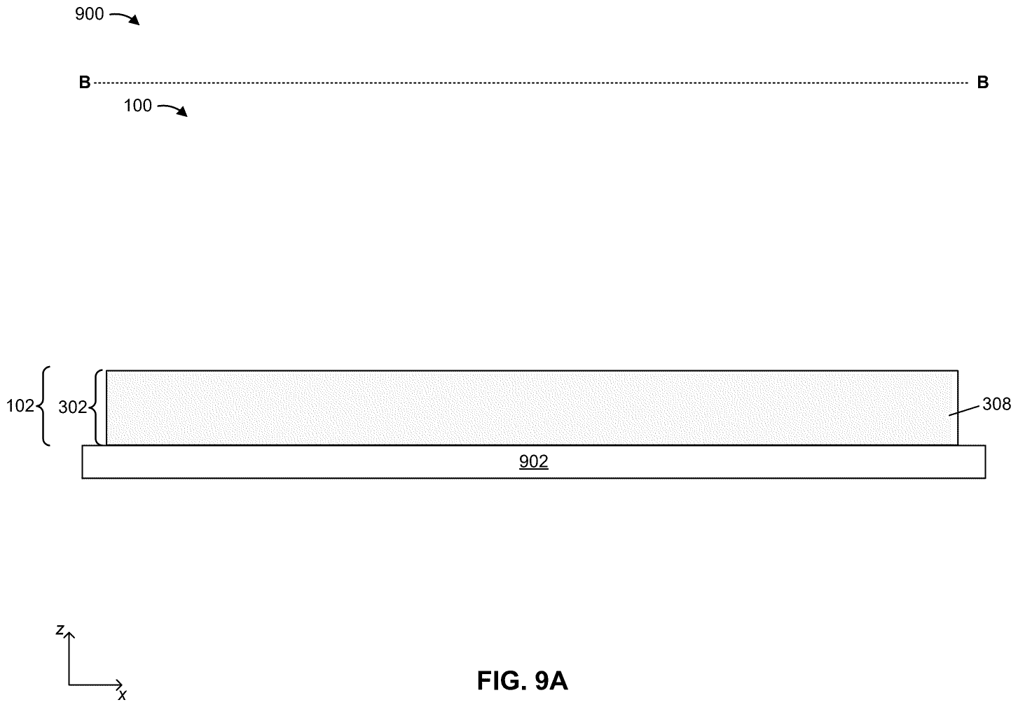

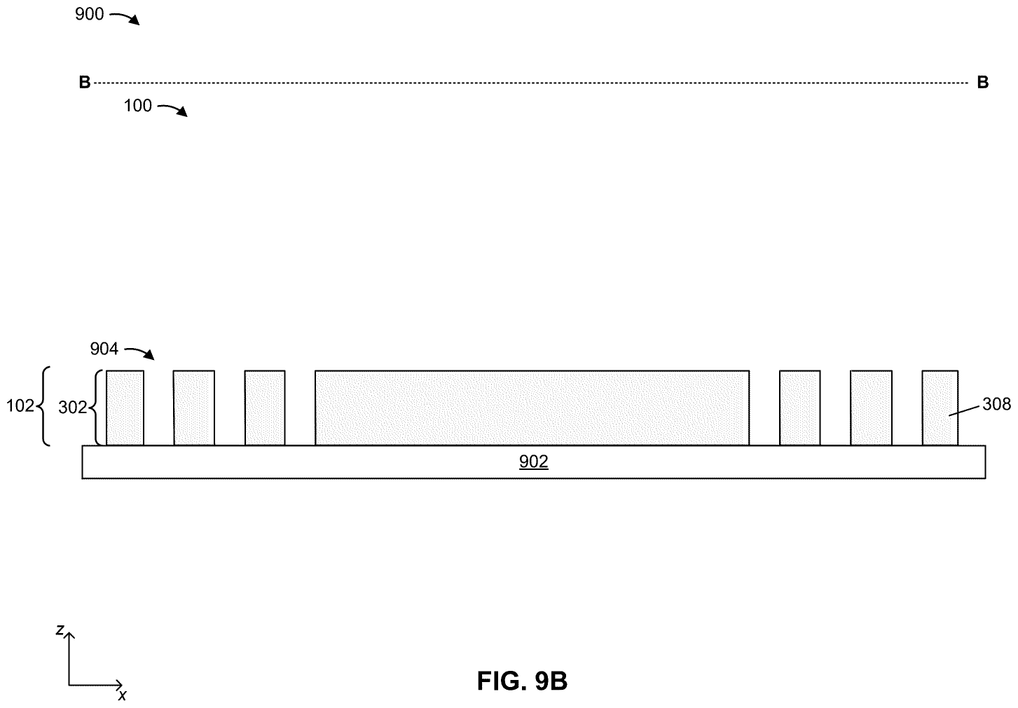

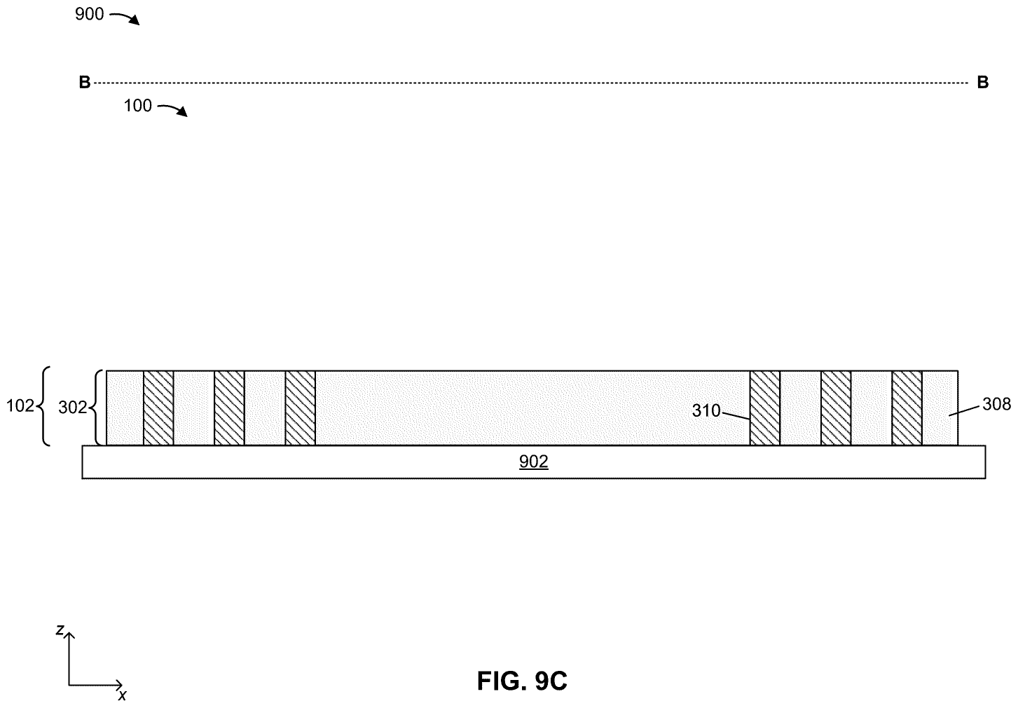

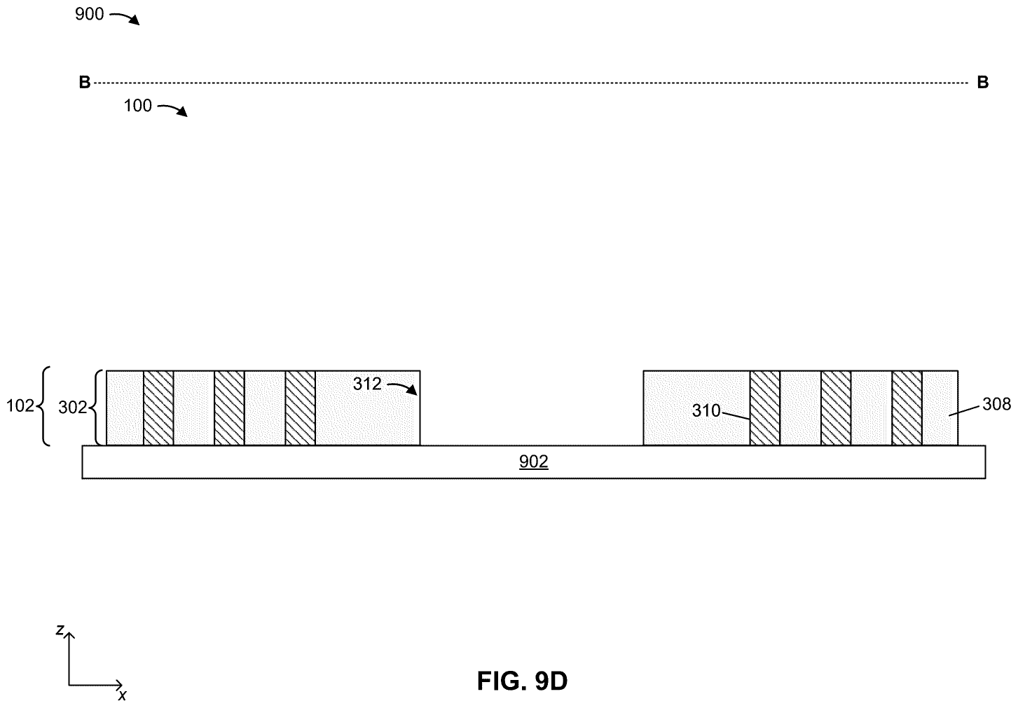

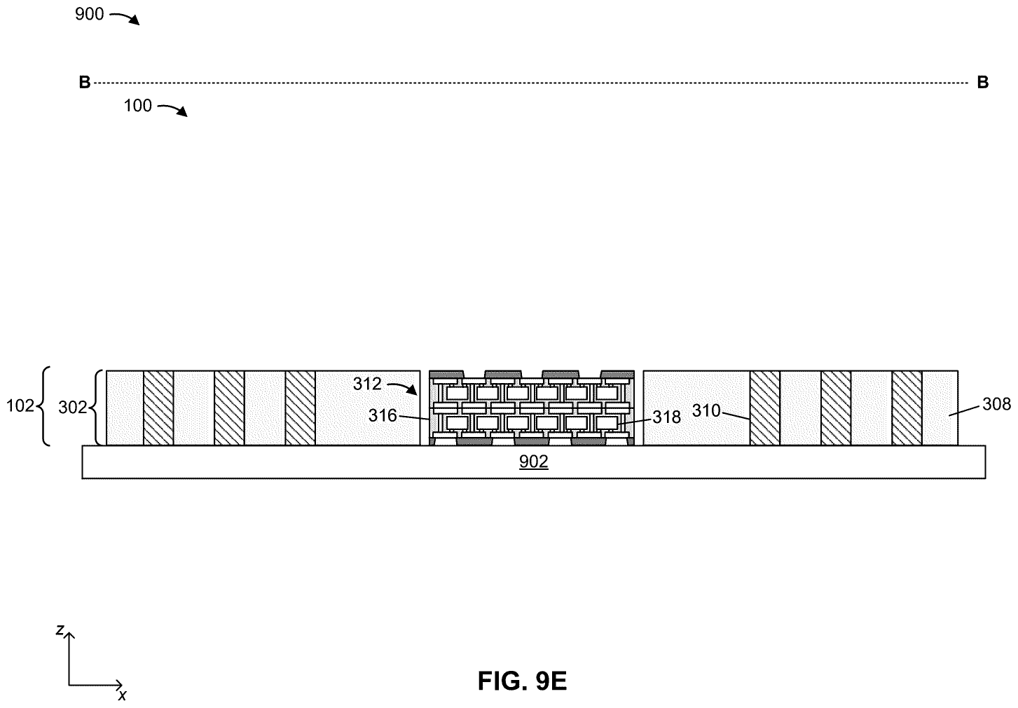

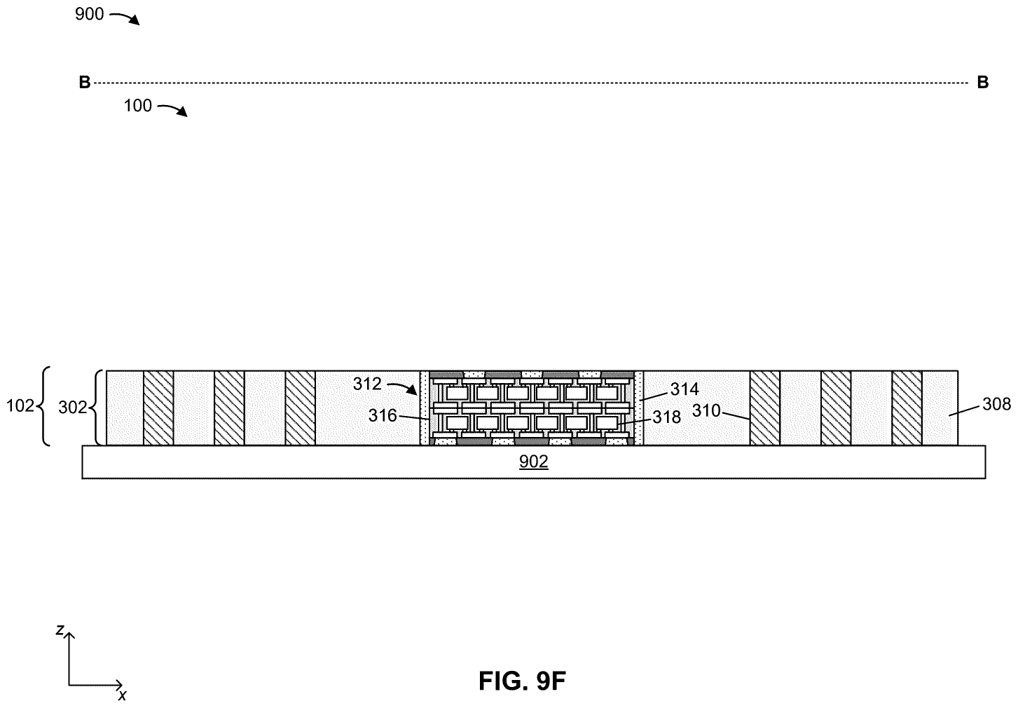

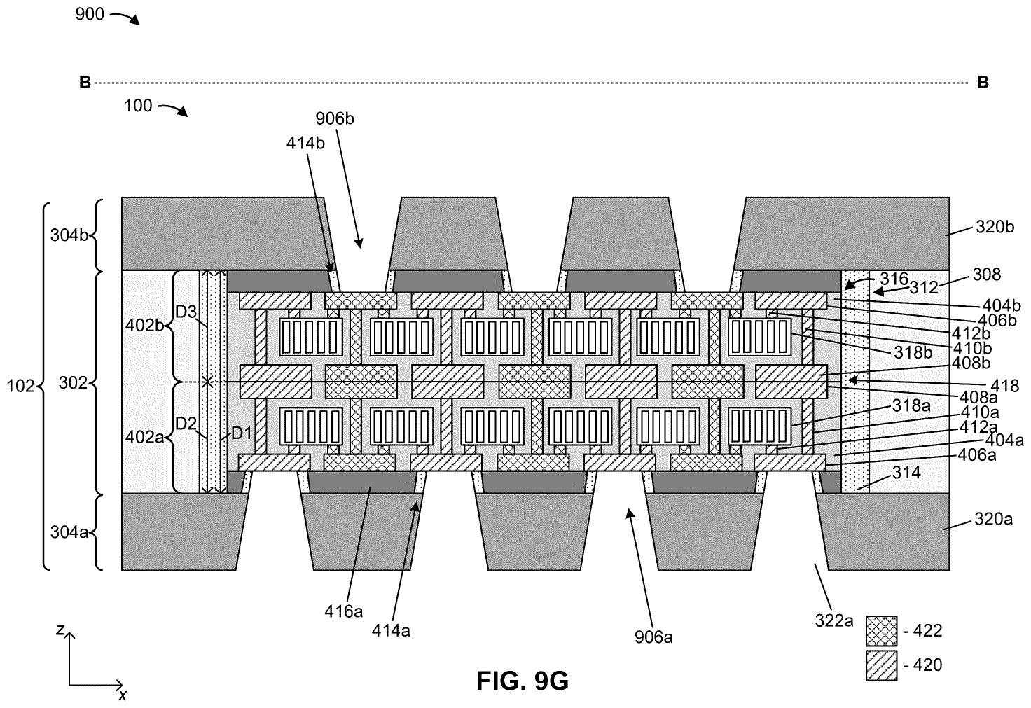

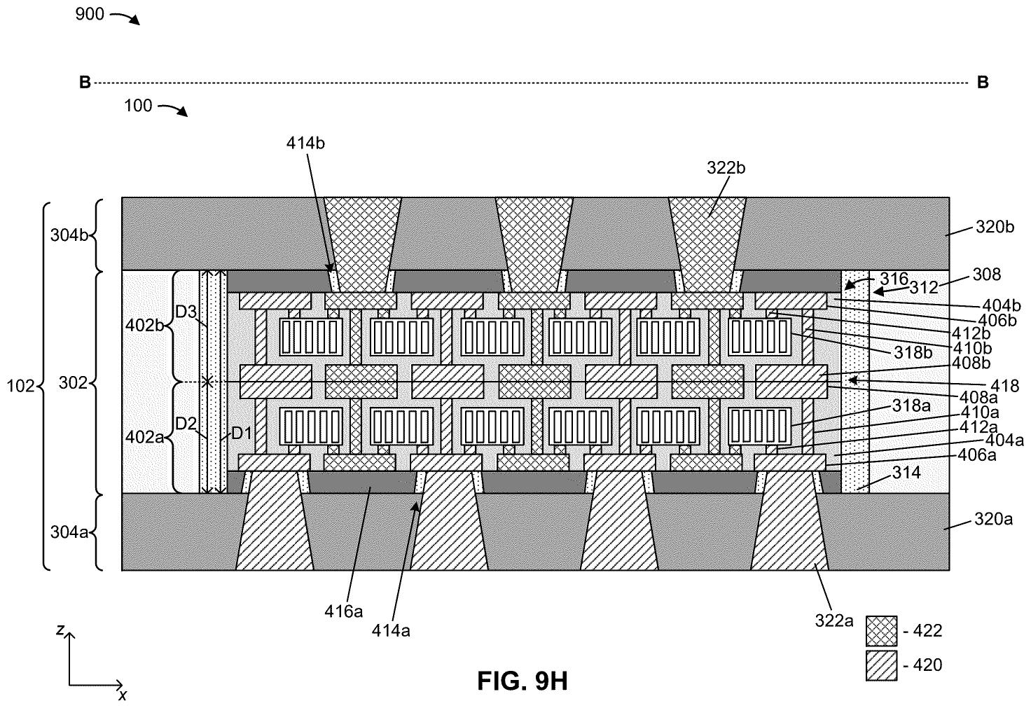

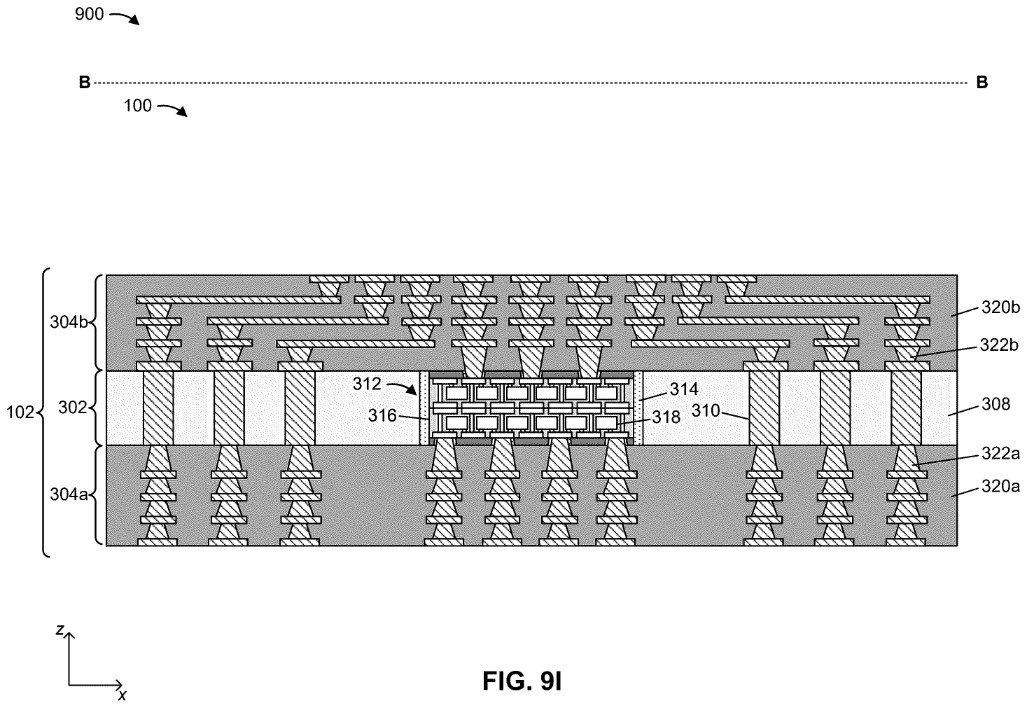

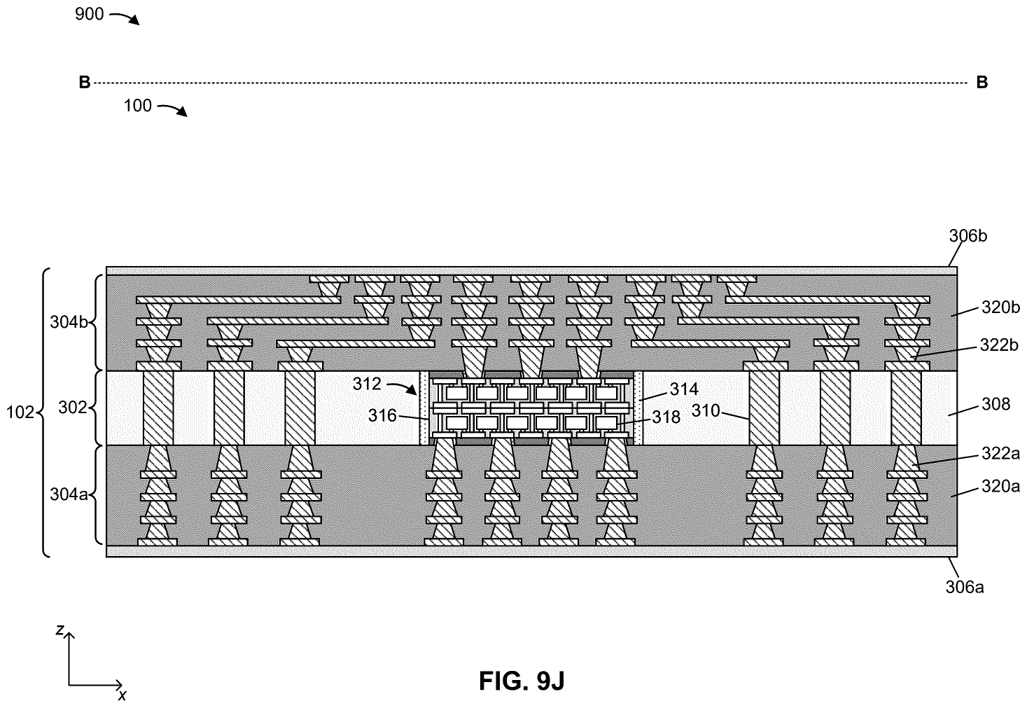

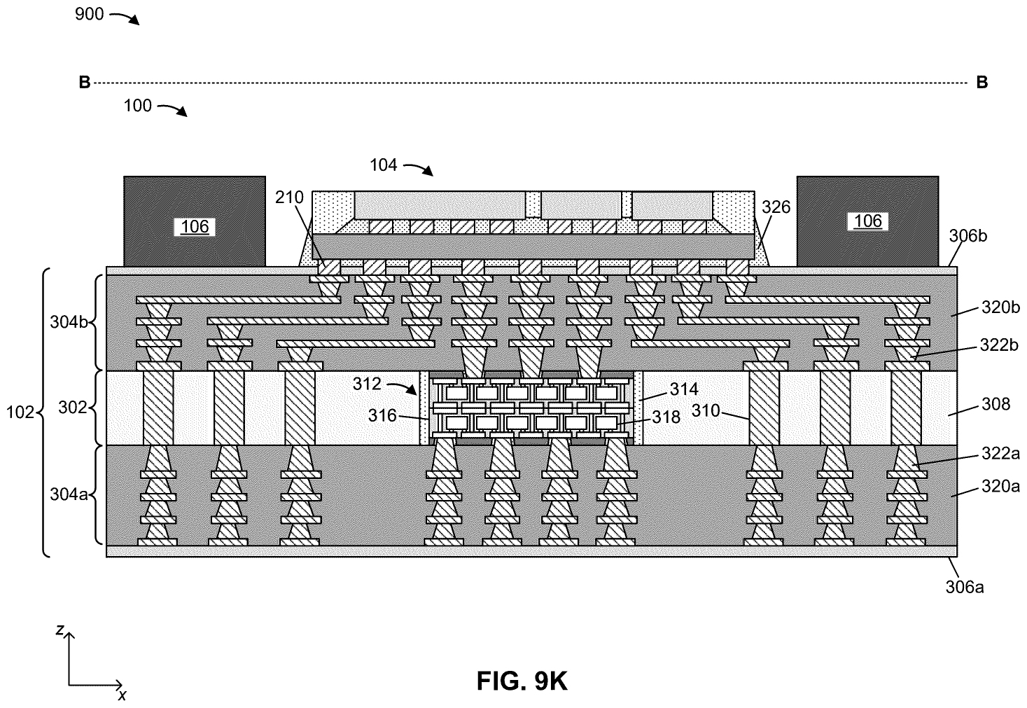

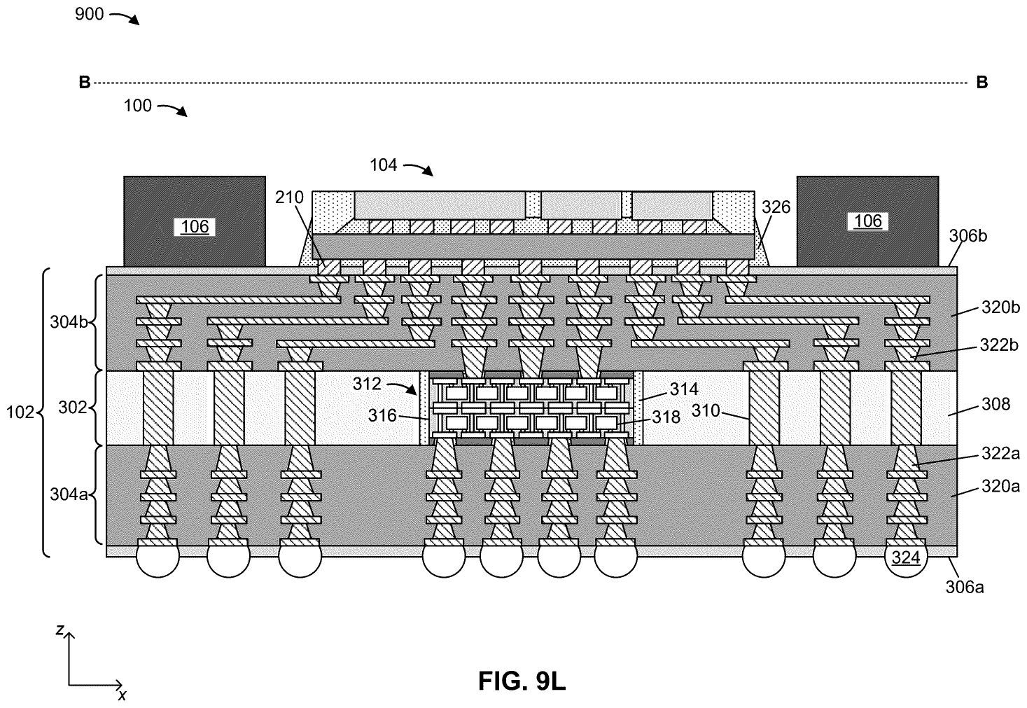

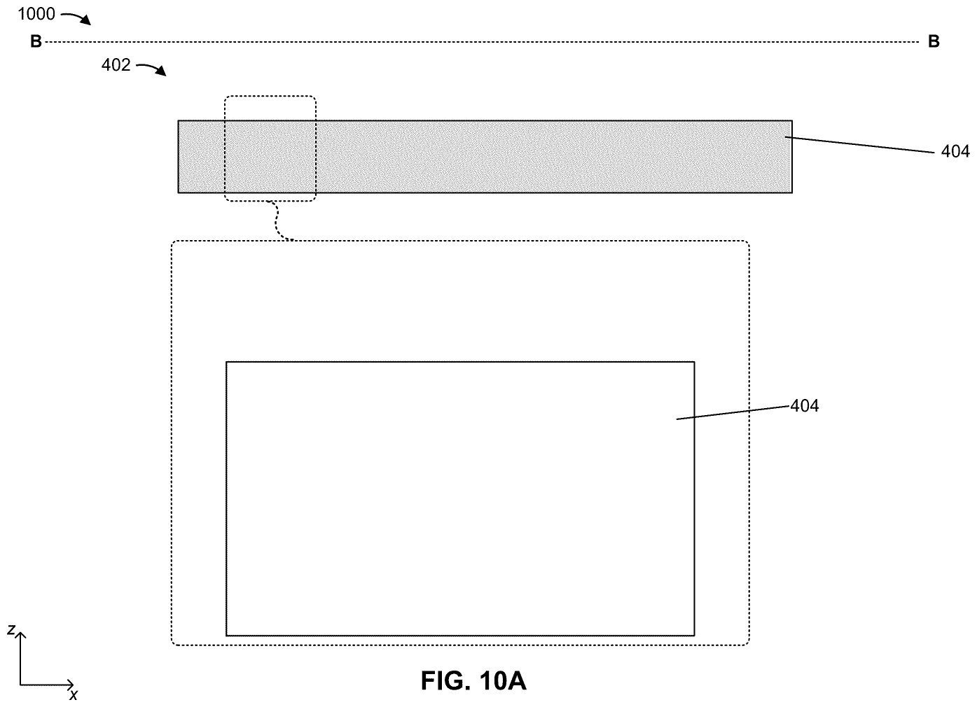

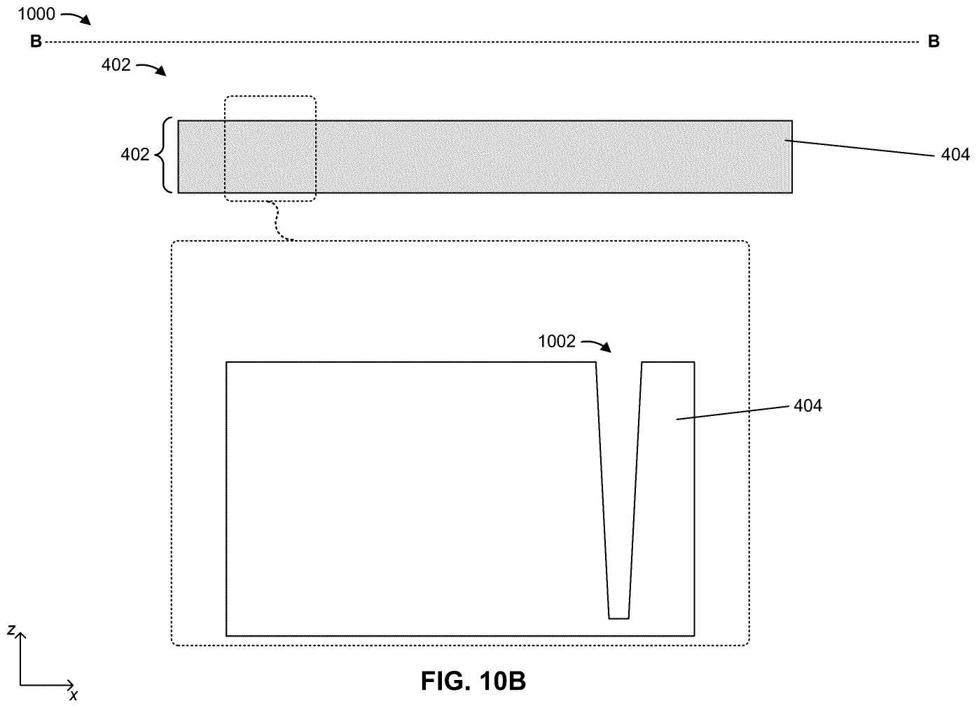

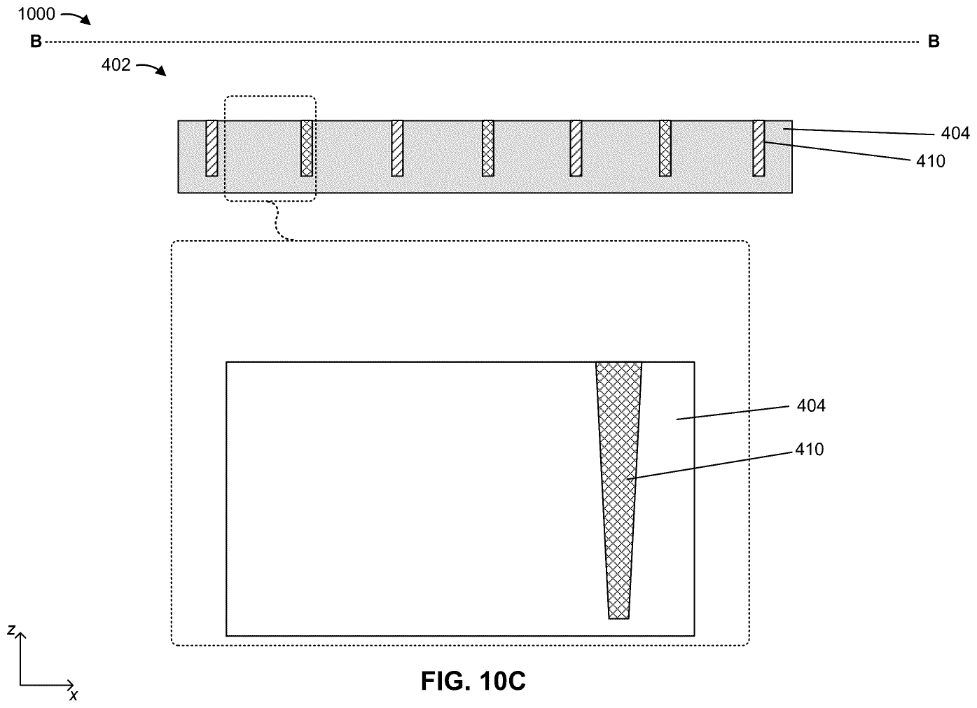

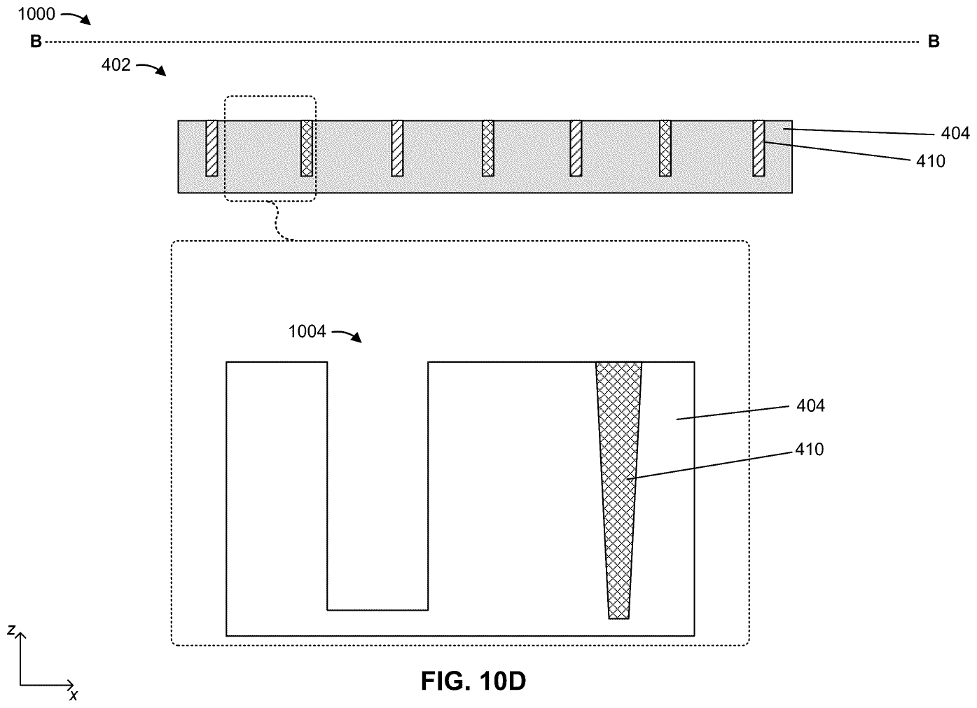

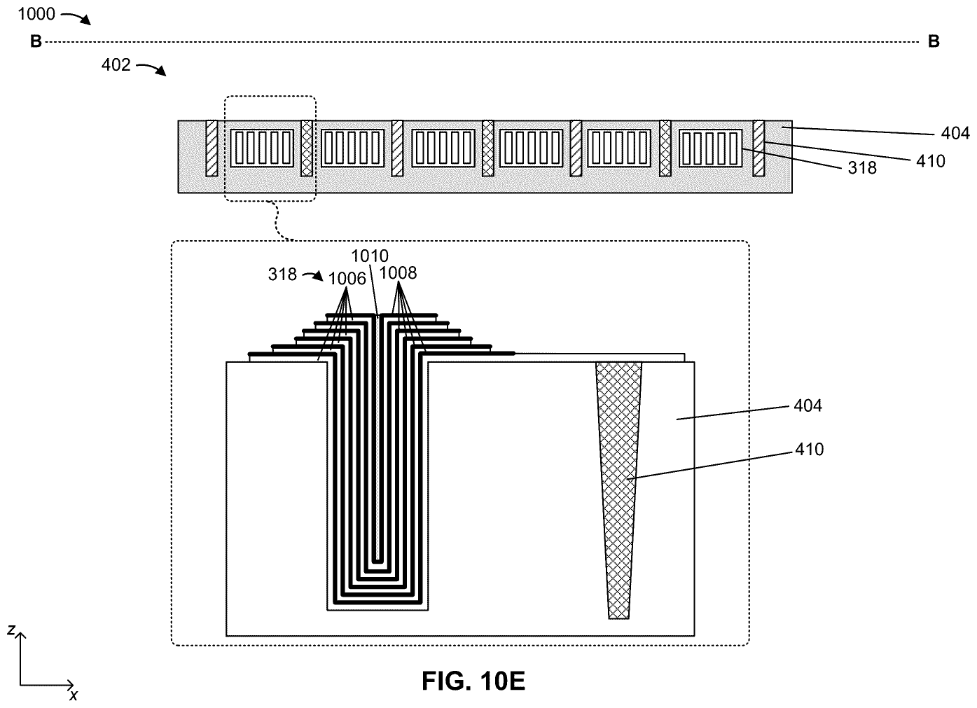

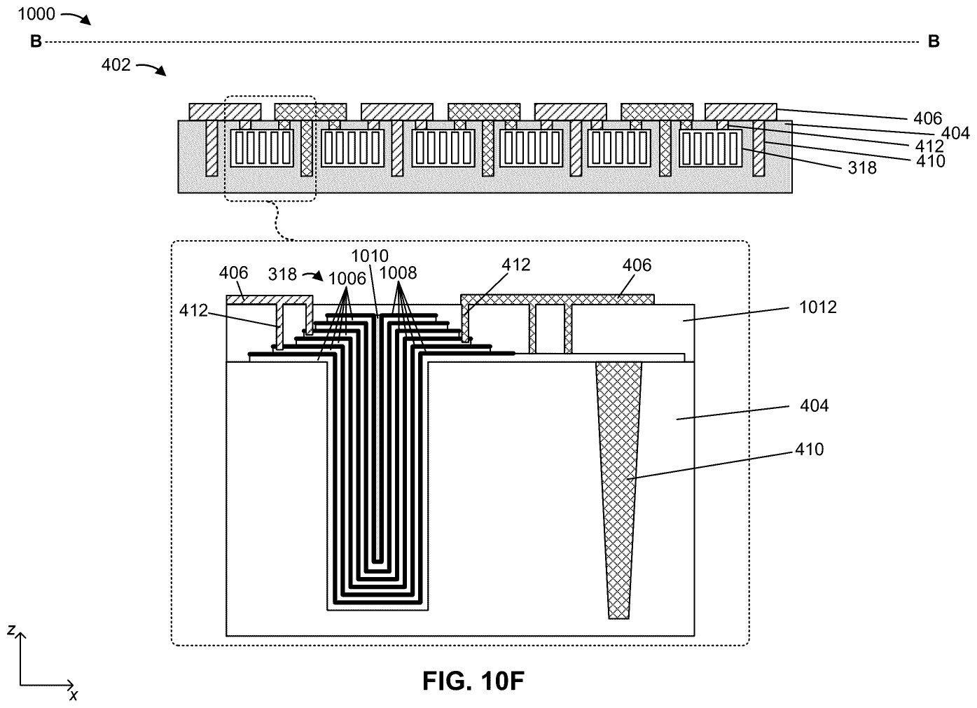

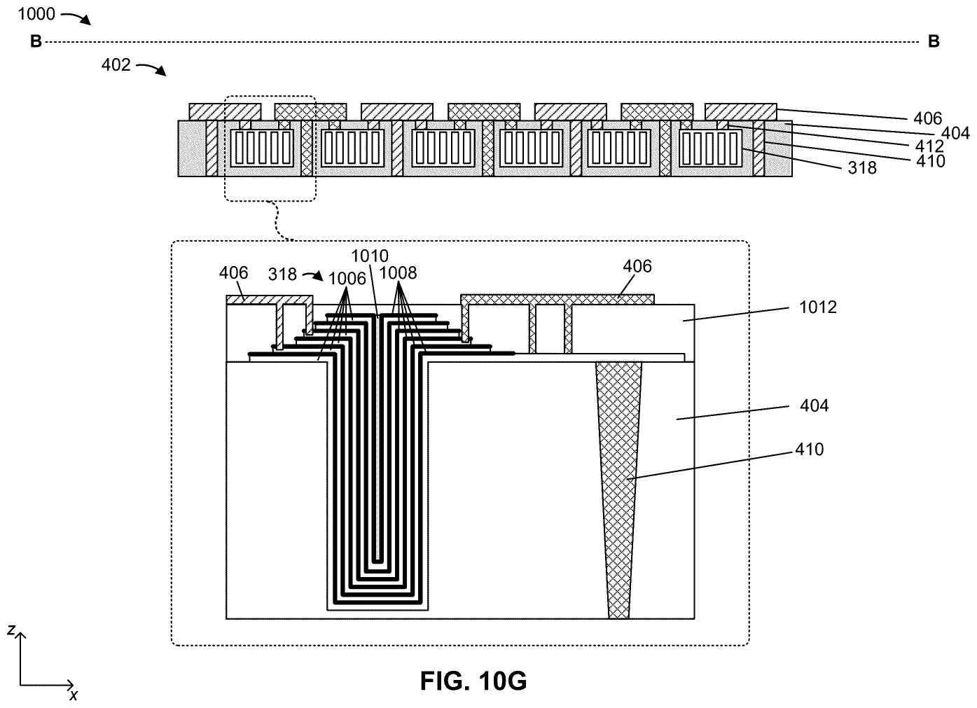

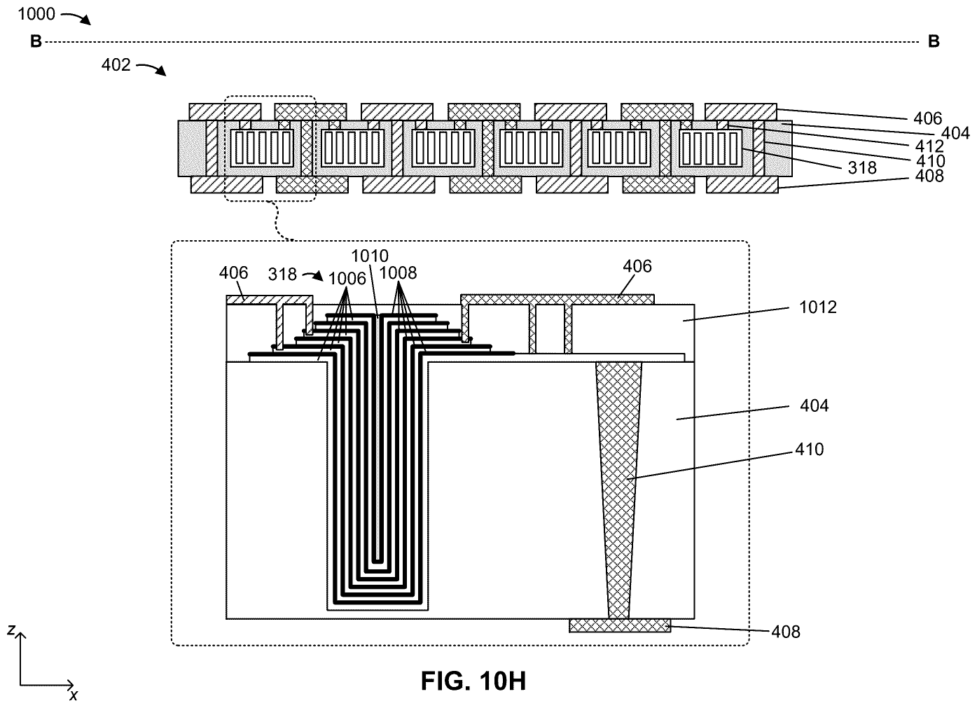

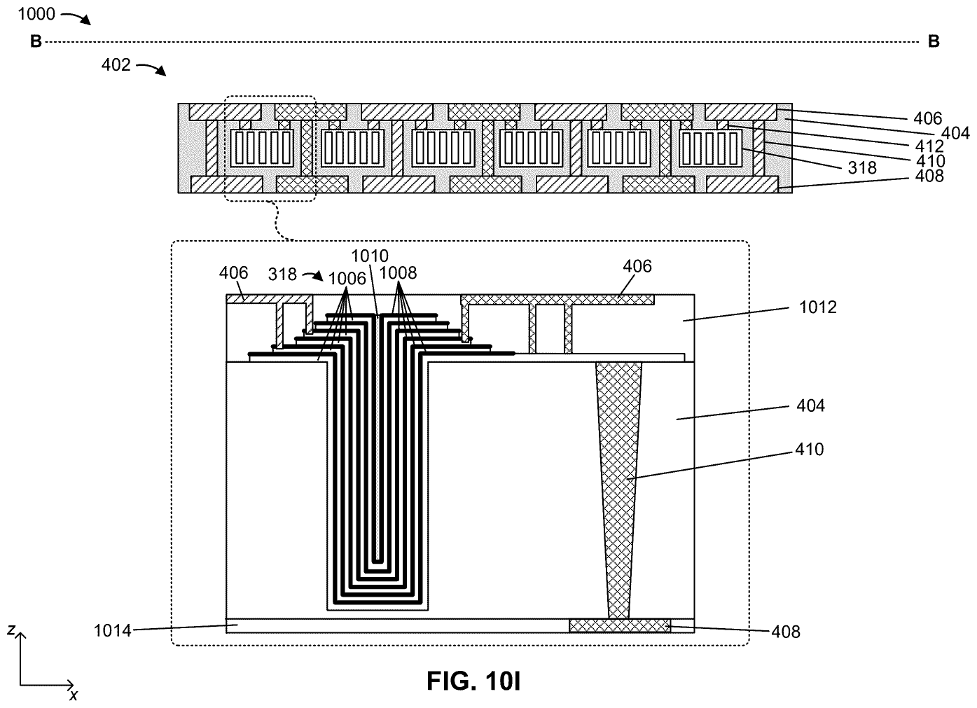

FIGS. 9A-9L are diagrams of an example implementation 900 of forming a semiconductor package 100 that includes an IPD package 316 described herein. One or more of semiconductor processing tools may be used to perform one or more of the operations described in connection with FIGS. 10A-10I, such as a deposition tool, an exposure tool (e.g., a photolithography tool), a developer tool, an etch tool, a planarization tool (e.g., a chemical-mechanical planarization (CMP) tool, a wafer grinding tool), a pick-and-place tool, a soldering tool, and/or another semiconductor processing tool.

Turning to FIG. 9A, the substrate layer 308 of the substrate core 302 of the package substrate 102 of the semiconductor package 100 may be provided. The substrate layer 308 may be provided on a carrier substrate 902 to facilitate processing of the substrate layer 308.

For example, and as shown in FIG. 9B, the substrate layer 308 may be provided on a carrier substrate 902 to facilitate recesses 904 to be formed fully through the substrate layer 308. In some implementations, a pattern in a photoresist layer is used to etch the substrate layer 308 to form the recesses 904. In these implementations, a deposition tool may be used to form the photoresist layer on the substrate layer 308 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the substrate layer 308 based on the pattern to form the recesses 904. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate layer 308 based on a pattern.

As shown in FIG. 9C, interconnect structures 310 may be formed in the recesses 904 such that the interconnect structures 310 extend through the substrate layer 308 of the substrate core 302. A deposition tool may be used to deposit the interconnect structures 310 using a chemical vapor deposition (CVD) technique, a physical vapor deposition (PVD) technique, an atomic layer deposition (ALD) technique, an electroplating technique, and/or another suitable deposition technique. The interconnect structures 310 may be deposited in one or more deposition operations. In some implementations, a seed layer is first deposited, and the interconnect structures 310 is deposited on the seed layer. In some implementations, a liner is first deposited in the recesses 904, and the interconnect structures 310 are deposited on the liner. The liner may include a barrier liner, an adhesion liner, and/or another type of liner. Examples of liner materials may include tantalum nitride (TaN), titanium nitride (TiN), and/or another suitable liner material. In some implementations, a planarization tool is used to perform a planarization operation (e.g., a chemical-mechanical planarization (CMP) operation) to planarize the interconnect structures 310 after the interconnect structures 310 are deposited.

As shown in FIG. 9D, a recess 312 may be formed through the substrate layer 308. In some implementations, a pattern in a photoresist layer is used to etch the substrate layer 308 to form the recess 312. In these implementations, a deposition tool may be used to form the photoresist layer on the substrate layer 308 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the substrate layer 308 based on the pattern to form the recess 312. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate layer 308 based on a pattern.

As shown in FIG. 9E, an IPD package 316 may be placed in the recess 312. In some implementations, the recess 312 fully extends through the substrate layer 308, and the IPD package 316 is placed on an exposed portion of the carrier substrate 902 exposed through the recess 312. A pick-and-place tool may be used to place the IPD package 316 in the recess 312.

As shown in FIG. 9F, the remaining area in the recess 312 may be filled in with filler material 314. A deposition tool or dispensing tool may be used to deposit the filler material 314 in the recess 312 such that the filler material 314 surrounds the IPD package 316 in the recess 312.

As shown in FIG. 9G, a first portion of the insulator layer 320a of the first redistribution structure 304a may be formed over the bottom side of the substrate core 302, and a first portion of the insulator layer 320b of the second redistribution structure 304b may be formed over the top side of the substrate core 302. The first portions of the insulator layers 320a and 320b may be deposited using a deposition tool.

As further shown in FIG. 9G, recesses 906a may be formed through the first portion of the insulator layer 320a and through recesses 414a in the passivation layer 416a of the IPD package 316 such that at least a subset of conductive pads 406a of the first IPD layer 402a of the IPD package 316 is exposed through the recesses 906a. Moreover, recesses 906b may be formed through the first portion of the insulator layer 320b and through recesses 414b in the passivation layer 416b of the IPD package 316 such that at least a subset of conductive pads 406b of the second IPD layer 402b of the IPD package 316 is exposed through the recesses 906b.

In some implementations, a pattern in a photoresist layer is used to etch the first portion of the insulator layer 320a and the filler material 314 to form the recesses 906a. In these implementations, a deposition tool may be used to form the photoresist layer on the first portion of the insulator layer 320a (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the first portion of the insulator layer 320a and the filler material 314 based on the pattern to form the recesses 906a. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses 906a based on a pattern.

In some implementations, a pattern in a photoresist layer is used to etch the first portion of the insulator layer 320b and the filler material 314 to form the recesses 906b. In these implementations, a deposition tool may be used to form the photoresist layer on the first portion of the insulator layer 320b (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the first portion of the insulator layer 320b and the filler material 314 based on the pattern to form the recesses 906b. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses 906b based on a pattern.

As shown in FIG. 9H, conductive structures 322a of the first redistribution structure 304a may be formed in the recesses 906a such that the conductive structures 322a land on the subset of conductive pads 406a exposed through the recesses 906a. A deposition tool may be used to deposit the conductive structures 322a using a CVD technique, a PVD technique, an ALD technique, an electroplating technique, and/or another suitable deposition technique. The conductive structures 322a may be deposited in one or more deposition operations. In some implementations, a seed layer is first deposited, and the conductive structures 322a is deposited on the seed layer. In some implementations, a liner is first deposited in the recesses 906a, and the conductive structures 322a are deposited on the liner. The liner may include a barrier liner, an adhesion liner, and/or another type of liner. Examples of liner materials may include tantalum nitride (TaN), titanium nitride (TiN), and/or another suitable liner material. In some implementations, a planarization tool is used to perform a planarization operation (e.g., a CMP operation) to planarize the conductive structures 322a after the conductive structures 322a are deposited.

As further shown in FIG. 9H, conductive structures 322b of the second redistribution structure 304b may be formed in the recesses 906b such that the conductive structures 322b land on the subset of conductive pads 406b exposed through the recesses 906b. A deposition tool may be used to deposit the conductive structures 322b using a CVD technique, a PVD technique, an ALD technique, an electroplating technique, and/or another suitable deposition technique. The conductive structures 322b may be deposited in one or more deposition operations. In some implementations, a seed layer is first deposited, and the conductive structures 322b is deposited on the seed layer. In some implementations, a liner is first deposited in the recesses 906b, and the conductive structures 322b are deposited on the liner. The liner may include a barrier liner, an adhesion liner, and/or another type of liner. Examples of liner materials may include tantalum nitride (TaN), titanium nitride (TiN), and/or another suitable liner material. In some implementations, a planarization tool is used to perform a planarization operation (e.g., a CMP operation) to planarize the conductive structures 322b after the conductive structures 322b are deposited.

As shown in FIG. 9I, additional portions of the insulator layer 320a may be formed for the first redistribution structure 304a, and additional layers of conductive structures 322a of the first redistribution structure 304a may be formed in the additional portions of the insulator layer 320a. In some implementations, the additional layers of conductive structures 322a of the first redistribution structure 304a are formed sequentially. For example, a first additional portion of the insulator layer 320a may be formed for the first redistribution structure 304a, a first additional layer of conductive structures 322a of the first redistribution structure 304a may be formed in the first additional portion of the insulator layer 320a, a second additional portion of the insulator layer 320a may be formed for the first redistribution structure 304a, a second additional layer of conductive structures 322a of the first redistribution structure 304a may be formed in the second additional portion of the insulator layer 320a, and so on.

As further shown in FIG. 9I, additional portions of the insulator layer 320b may be formed for the second redistribution structure 304b, and additional layers of conductive structures 322b of the second redistribution structure 304b may be formed in the additional portions of the insulator layer 320b. In some implementations, the additional layers of conductive structures 322b of the second redistribution structure 304b are formed sequentially. For example, a first additional portion of the insulator layer 320b may be formed for the second redistribution structure 304b, a first additional layer of conductive structures 322b of the second redistribution structure 304b may be formed in the first additional portion of the insulator layer 320b, a second additional portion of the insulator layer 320b may be formed for the second redistribution structure 304b, a second additional layer of conductive structures 322b of the second redistribution structure 304b may be formed in the second additional portion of the insulator layer 320b, and so on.

As shown in FIG. 9J, a passivation layer 306a may be formed over the first redistribution structure 304a, and a passivation layer 306b may be formed over the second redistribution structure 304b. A deposition tool may be used to deposit the passivation layers 306a and 306b using a CVD technique, a PVD technique, an ALD technique, and/or another suitable deposition technique. In some implementations, a planarization tool may be used to perform a planarization operation (e.g., a CMP operation) to planarize the passivation layers 306a and 306b.

As shown in FIG. 9K, a pick-and-place tool may be used to place one or more semiconductor die packages 104 on the package substrate 102 of the semiconductor package 100. For example, the one or more semiconductor die packages 104 may be placed on conductive structures 322b of the second redistribution structure 304b, and a solder tool may be used to perform a solder operation (e.g., wave solder operation, a reflow solder operation) to attach the one or more semiconductor die packages 104 to the package substrate 102. As another example, a bonding tool may be used to perform a bonding operation to bond the connection structures 210 of the one or more semiconductor die packages 104 to the conductive structures 322b of the second redistribution structure 304b.

As further shown in FIG. 9K, the stiffener structure 106 may be placed on the package substrate 102. The stiffener structure 106 may be attached second redistribution structure 304b using an epoxy, and adhesive, and/or may otherwise be secured to the second redistribution structure 304b.

As shown in FIG. 9L, package connection structures 324 may be attached to the bottom of the package substrate 102 of the semiconductor package 100. For example, solder balls or UBM structures may be attached a layer of conductive structures 322a at the bottom of the first redistribution structure 304a. The package connection structures 324 may be attached to the bottom of the package substrate 102 using a solder mask.

As indicated above, FIGS. 9A-9L are provided as an example. Other examples may differ from what is described with regard to FIGS. 9A-9L.

FIGS. 10A-10I are diagrams of an example implementation 1000 of forming an IPD layer 402 that may be included in an IPD package 316 described herein. One or more of semiconductor processing tools may be used to perform one or more of the operations described in connection with FIGS. 10A-10I, such as a deposition tool, an exposure tool (e.g., a photolithography tool), a developer tool, an etch tool, a planarization tool (e.g., a CMP tool, a wafer grinding tool), and/or another semiconductor processing tool.

Turning to FIG. 10A, a substrate layer 404 of the IPD layer 402 may be provided. The substrate layer 404 may be provided as a semiconductor wafer (e.g., a silicon (Si) wafer, a silicon-on-insulator (SOI) wafer), a semiconductor die, and/or another type of semiconductor workpiece. In some implementations, the IPD layer 402 may be manufactured on a semiconductor wafer along with a plurality of other IPD layers 402. In these implementations, one or more of the semiconductor processing operations described in connection with FIGS. 10A-10I may include wafer-level semiconductor processing operations.

As shown in FIG. 10B, recesses 1002 may be formed in a first side of the substrate layer 404. The recesses 1002 may be formed as part of forming interconnect structures in the substrate layer 404 of the IPD layer 402. In some implementations, a pattern in a photoresist layer is used to etch the substrate layer 404 to form the recesses 1002. In these implementations, a deposition tool may be used to form the photoresist layer on the first side of the substrate layer 404 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the substrate layer 404 from the first side of the substrate layer 404 based on the pattern to form the recesses 1002. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate layer 404 based on a pattern.

As shown in FIG. 10C, interconnect structures 410 may be formed in the recesses 1002 from the first side of the substrate layer 404. A deposition tool may be used to deposit the interconnect structures 410 using a CVD technique, a PVD technique, an ALD technique, an electroplating technique, and/or another suitable deposition technique. The interconnect structures 410 may be deposited in one or more deposition operations. In some implementations, a seed layer is first deposited, and the interconnect structures 410 is deposited on the seed layer. In some implementations, a liner is first deposited in the recesses 1002, and the interconnect structures 410 are deposited on the liner. The liner may include a barrier liner, an adhesion liner, and/or another type of liner. Examples of liner materials may include tantalum nitride (TaN), titanium nitride (TiN), and/or another suitable liner material. In some implementations, a planarization tool is used to perform a planarization operation (e.g., a CMP operation) to planarize the interconnect structures 410 after the interconnect structures 410 are deposited.

As shown in FIG. 10D, recesses 1004 may be formed in the first side of the substrate layer 404. The recesses 1004 may be formed as part of forming passive device structures 318 in the substrate layer 404 of the IPD layer 402. In some implementations, the recesses 1004 are formed to a depth in the substrate layer 404 that is less than the depth of the interconnect structures 410. This enables a subsequent backside planarization or wafer grinding operation to be performed to expose the bottom ends of the interconnect structures 410 without exposing the bottoms of the passive device structures 318.

In some implementations, a pattern in a photoresist layer is used to etch the substrate layer 404 to form the recesses 1004. In these implementations, a deposition tool may be used to form the photoresist layer on the first side of the substrate layer 404 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the substrate layer 404 from the first side of the substrate layer 404 based on the pattern to form the recesses 1004. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate layer 404 based on a pattern.

As shown in FIG. 10E, passive device structures 318 may be formed in the recesses 1004. FIG. 10E illustrates an example of forming capacitors in the recesses 1004. The capacitors may extend into the substrate layer 404 from the first side of the substrate layer 404. In the example in FIG. 10E, a passive device structure 318 (e.g., a capacitor) may include a plurality of conductive layers 1006 and a plurality of dielectric layers 1008. The conductive layers 1006 and the dielectric layers 1008 may be arranged in an alternating configuration in the passive device structure 318. For example, a first conductive layer 1006 may be included in the passive device structure 318, a first dielectric layer 1008 may be included over the first conductive layer 1006, a second conductive layer 1006 may be included over the first dielectric layer 1008, and so on. A deposition tool may be used to conformally deposit (e.g., using CVD, ALD, and/or another conformal deposition technique) the conductive layers 1006 and the dielectric layer 1008 in the recess 1004 such that the conductive layers 1006 and the dielectric layer 1008 conform to the profiles of the sidewalls and bottom surface of the recess 1004.

A first subset of the conductive layers 1006 may correspond to first electrode layers of the passive device structure 318, and a second subset of the conductive layers 1006 may correspond to second electrode layers of the passive device structure 318. The dielectric layers 1008 may be included between the first electrode layers and the second electrode layers, resulting in a metal-insulator-metal (MIM) arrangement for the passive device structure 318.

In some implementations, a bottom-most conductive layer 1006 of the passive device structure 318 may be formed such that the bottom-most conductive layer 1006 extends along the top side of the substrate layer 404 over an interconnect structure 410. In this way, the bottom-most conductive layer 1006 is electrically connected to the interconnect structure 410.

Alternatively, the bottom-most conductive layer 1006 is formed such that the bottom-most conductive layer 1006 is spaced apart and not in direct contact with the interconnect structure 410.

The conductive layers 1006 may include one or more conductive materials such as a conductive metal (e.g., copper (Cu), tungsten (W), titanium (Ti), tantalum (Ta), ruthenium (Ru), cobalt (Co)), a conductive ceramic (e.g., tantalum nitride (TaN), titanium nitride (TiN)), and/or another type of conductive material. The dielectric layers 1008 may include one or more dielectric materials such as an oxide (e.g., silicon oxide (SiOₓ)), a nitride (e.g., silicon nitride (SiₓN_{y}), and/or another suitable dielectric material.

As further shown in FIG. 10E, the remaining area in the recess 1004 may be filled in with a dielectric filler 1010. Alternatively, a conductive layer 1006 or a dielectric layer 1008 may fill in the remaining area in the recess 1004. A deposition tool may be used to deposit the dielectric filler 1010 using a CVD technique, a PVD technique, an ALD technique, an electroplating technique, and/or another suitable deposition technique.

As shown in FIG. 10F, a dielectric layer 1012 may be formed over the top side of the substrate layer 404 such that the tops of the passive device structures 318 and the tops of the interconnect structures 410 are covered by the dielectric layer 1012. A deposition tool may be used to deposit the dielectric layer 1012 using a CVD technique, a PVD technique, an ALD technique, and/or another suitable deposition technique. In some implementations, a planarization tool may be used to perform a planarization operation (e.g., a CMP operation) to planarize the dielectric layer 1012.

As further shown in FIG. 10F, the contacts 412 of the IPD layer 402 may be formed over the first side of the substrate layer 404 such that the contacts 412 extend through the dielectric layer 1012 and contact one or more of the conductive layers 1006 of the passive device structures 318. To form the contacts 412, recesses may be formed through the dielectric layer 1012 and to one or more of the conductive layers 1006. In some implementations, a pattern in a photoresist layer is used to etch the dielectric layer 1012 to form the recesses. In these implementations, a deposition tool may be used to form the photoresist layer on the dielectric layer 1012 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dielectric layer 1012 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 1012 based on a pattern.

A deposition tool may be used to deposit the contacts 412 in the recesses using a CVD technique, a PVD technique, an ALD technique, an electroplating technique, and/or another suitable deposition technique. The contacts 412 may be deposited in one or more deposition operations. In some implementations, a seed layer is first deposited, and the contacts 412 are deposited on the seed layer. In some implementations, a liner is first deposited in the recesses, and the contacts 412 are deposited on the liner. The liner may include a barrier liner, an adhesion liner, and/or another type of liner. Examples of liner materials may include tantalum nitride (TaN), titanium nitride (TiN), and/or another suitable liner material. In some implementations, a planarization tool is used to perform a planarization operation (e.g., a CMP operation) to planarize the contacts 412 after the contacts 412 are deposited.

As further shown in FIG. 10F, the conductive pads 406 of the IPD layer 402 may be formed over the first side of the substrate layer 404 such that the conductive pads 406 are electrically connected to the contacts 412. In some implementations, additional material of the interconnect structures 410 are formed in the dielectric layer 1012, and the conductive pads 406 are formed on the interconnect structures 410. In some implementations, and as shown in the example in FIG. 10F, the interconnect structures 410 are indirectly connected to the conductive pads 406 through one or more conductive layers 1006 of the passive device structures 318.

A deposition tool may be used to deposit the conductive pads 406 using a CVD technique, a PVD technique, an ALD technique, an electroplating technique, and/or another suitable deposition technique. The conductive pads 406 may be deposited in one or more deposition operations. In some implementations, a seed layer is first deposited, and the conductive pads 406 are deposited on the seed layer. In some implementations, a liner is first deposited, and the conductive pads 406 are deposited on the liner. The liner may include a barrier liner, an adhesion liner, and/or another type of liner. Examples of liner materials may include tantalum nitride (TaN), titanium nitride (TiN), and/or another suitable liner material. In some implementations, a planarization tool is used to perform a planarization operation (e.g., a CMP operation) to planarize the conductive pads 406 after the conductive pads 406 are deposited.

As shown in FIG. 10G, a planarization tool may be used to planarize a second side (e.g., a bottom side) of the substrate layer 404 opposing the first side. In some implementations, the planarization tool may include a wafer grinding tool that is used to perform a grinding operation to remove material from the second side of the substrate layer 404. In some implementations, the planarization tool may include a CMP tool that is used to perform a CMP operation to remove material from the second side of the substrate layer 404. Removal of material from the second side of the substrate layer 404 exposes the bottoms of the interconnect structures 410 through the second side of the substrate layer 404.

As shown in FIG. 10H, conductive pads 408 of the IPD layer 402 may be formed on the second side of the substrate layer 404 such that at least a subset of the conductive pads 408 are connected to the interconnect structures 410. A deposition tool may be used to deposit the conductive pads 408 using a CVD technique, a PVD technique, an ALD technique, an electroplating technique, and/or another suitable deposition technique. The conductive pads 408 may be deposited in one or more deposition operations. In some implementations, a seed layer is first deposited, and the conductive pads 408 are deposited on the seed layer. In some implementations, a liner is first deposited, and the conductive pads 408 are deposited on the liner. The liner may include a barrier liner, an adhesion liner, and/or another type of liner. Examples of liner materials may include tantalum nitride (TaN), titanium nitride (TiN), and/or another suitable liner material. In some implementations, a planarization tool is used to perform a planarization operation (e.g., a CMP operation) to planarize the conductive pads 408 after the conductive pads 408 are deposited.

As shown in FIG. 10I, a bonding dielectric layer 1014 may be formed over the second side of the substrate layer 404. A deposition tool may be used to deposit the bonding dielectric layer 1014 using a CVD technique, a PVD technique, an ALD technique, and/or another suitable deposition technique. In some implementations, a planarization tool may be used to perform a planarization operation (e.g., a CMP operation) to planarize the bonding dielectric layer 1014 (e.g., such that the conductive pads 408 are exposed through the bonding dielectric layer 1014).

As indicated above, FIGS. 10A-10I are provided as an example. Other examples may differ from what is described with regard to FIGS. 10A-10I.

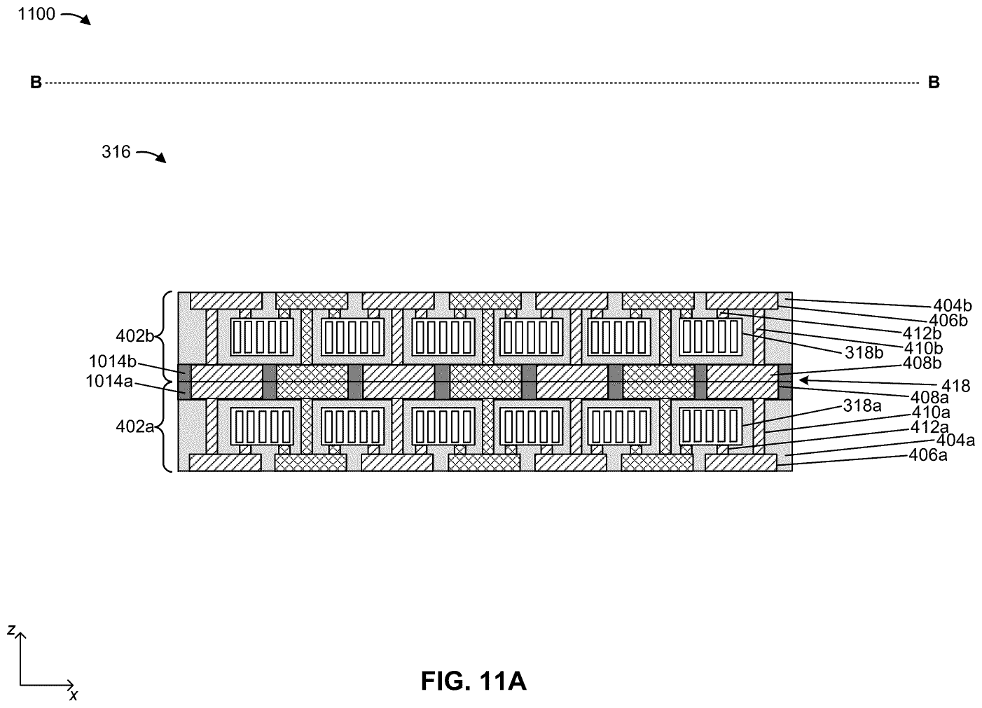

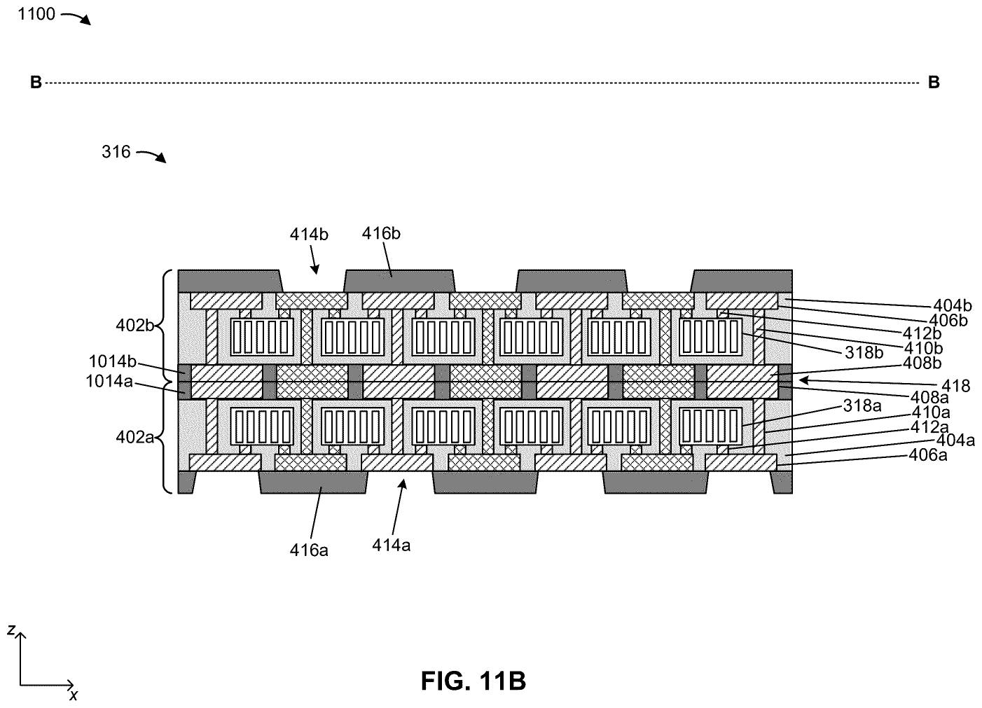

FIGS. 11A and 11B are diagrams of an example implementation 1100 of forming an IPD package 316 described herein. As shown in FIG. 11A, the IPD package 316 may be formed by bonding two or more IPD layers together such that the two or more IPD layers are stacked and vertically arranged in the IPD package 316. For example, a bonding tool may be used to bond a first IPD layer 402a and a second IPD layer 402b together to form the IPD package 316. The bonding tool may be used to form metal-to-metal bonds between conductive pads 408a of the first IPD layer 402a with conductive pads 408b of the second IPD layer 402b, and to form dielectric-to-dielectric bonds between a bonding dielectric layer 1014a of first IPD layer 402a and a bonding dielectric layer 1014b of the second IPD layer 402b. In some implementations, additional IPD layers may be bonded to the IPD package 316 in a similar manner.

As shown in FIG. 11B, the top and bottom surfaces of the IPD package 316 may be passivated. For example, a passivation layer 416a may be formed on the bottom side (e.g., the exposed side) of the first IPD layer 402a, and/or a passivation layer 416b may be formed on the top side (e.g., the exposed side) of the second IPD layer 402b. The passivation layer 416a may be formed such that recesses 414a in the passivation layer 416a are provided, such that at least a subset of the conductive pads 406a of the first IPD layer 402a are exposed through the passivation layer 416a. Similarly, the passivation layer 416b may be formed such that recesses 414b in the passivation layer 416b are provided, such that at least a subset of the conductive pads 406b of the second IPD layer 402b are exposed through the passivation layer 416b.

In some implementations, the passivation layers 416a and 416b may be formed of one or more dielectric materials, and a deposition tool is used to deposit the passivation layers 416a and 416b using a PVD technique, a CVD technique, an ALD technique, and/or another suitable deposition technique. In some implementations, the passivation layers 416a and 416b may be formed of a solder resist material or a polymer material, and the passivation layers 416a and 416b are dispensed or placed on the IPD package 316.

As indicated above, FIGS. 11A and 11B are provided as an example. Other examples may differ from what is described with regard to FIGS. 11A and 11B.

FIGS. 12A and 12B are diagrams of an example semiconductor package 1200 described herein. FIG. 12A illustrates a top view of the semiconductor package 1200. FIG. 12B illustrates a cross-section view of the semiconductor package 1200 along the line C-C in the x-direction in FIG. 12A.

As shown in FIGS. 12A and 12B, the semiconductor package 1200 includes a similar combination of arrangement of layers and/or structures as the semiconductor package 100.

Accordingly, the semiconductor package 1200 may be formed by similar semiconductor processing operations as illustrated and described in connection with FIGS. 9A-9L. However, and as illustrated in FIG. 12B, the semiconductor package 1200 includes a surface-mounted IPD package 316 that is attached to conductive structures 322b on the top side of the second redistribution structure 304b of the package substrate 102 of the semiconductor package 1200 using package connection structures 1202 instead of an IPD package embedded in the substrate core 302 of the package substrate 102.

The IPD package 316 may be located laterally adjacent to one or more semiconductor die packages 104 and may be located within a perimeter of the stiffener structure 106. Additionally and/or alternatively, an IPD package 316 may be surface mounted to conductive structures 322a on the bottom side of the first redistribution structure 304a of the package substrate 102 of the semiconductor package 1200 using package connection structures 1202.

The IPD package 316 illustrated in FIGS. 12A and 12B may be formed in a similar manner as described in connection with FIGS. 10A-101, 11A, and/or 11B, and may include one or more of the arrangements of passive device structures 318 illustrated in one or more of FIGS. 4-8. In addition, the package connection structures 1202 may be placed on conductive pads (e.g., conductive pads 406a, conductive pads 406b) of the IPD package 316, and the package connection structures 1202 may include solder balls, micro-bumps, UBM structures, and/or other types of package connection structures.

As indicated above, FIGS. 12A and 12B are provided as an example. Other examples may differ from what is described with regard to FIGS. 12A and 12B.

FIG. 13 is a diagram of an example semiconductor package 1300 described herein. FIG. 13 illustrates a cross-section view of the semiconductor package 1300. As shown in FIG. 13, the semiconductor package 1300 includes a similar combination of arrangement of layers and/or structures as the semiconductor package 100. Accordingly, the semiconductor package 1300 may be formed by similar semiconductor processing operations as illustrated and described in connection with FIGS. 9A-9L.

However, and as illustrated in FIG. 13, the semiconductor package 1300 includes a surface-mounted IPD package 316a that is attached to conductive structures 322b on the top side of the second redistribution structure 304b of the package substrate 102 of the semiconductor package 1300 using package connection structures 1202, in addition to the IPD package 316b embedded in the substrate core 302 of the package substrate 102 of the semiconductor package 1300.

The IPD package 316a may be located laterally adjacent to one or more semiconductor die packages 104 and may be located within a perimeter of the stiffener structure 106. Additionally and/or alternatively, an IPD package 316a may be surface mounted to conductive structures 322a on the bottom side of the first redistribution structure 304a of the package substrate 102 of the semiconductor package 1300 using package connection structures 1202.

The IPD package 316b may be located vertically between the first redistribution structure 304a and the second redistribution structure 304b of the package substrate 102. The IPD package 316b may be electrically connected on a first side of the IPD package 316b to conductive structures 322a of the first redistribution structure 304a, and may be electrically connected on a second side of the IPD package 316b vertically opposite the first side to conductive structures 322b of the second redistribution structure 304b.

The IPD packages 316a and 316b illustrated in FIG. 13 may be formed in a similar manner as described in connection with FIGS. 10A-101, 11A, and/or 11B, and may include one or more of the arrangements of passive device structures 318 illustrated in one or more of FIGS. 4-8. In addition, the package connection structures 1202 of the IPD package 316a may be placed on conductive pads (e.g., conductive pads 406a, conductive pads 406b) of the IPD package 316a, and the package connection structures 1202 may include solder balls, micro-bumps, UBM structures, and/or other types of package connection structures.

As indicated above, FIG. 13 is provided as an example. Other examples may differ from what is described with regard to FIG. 13.

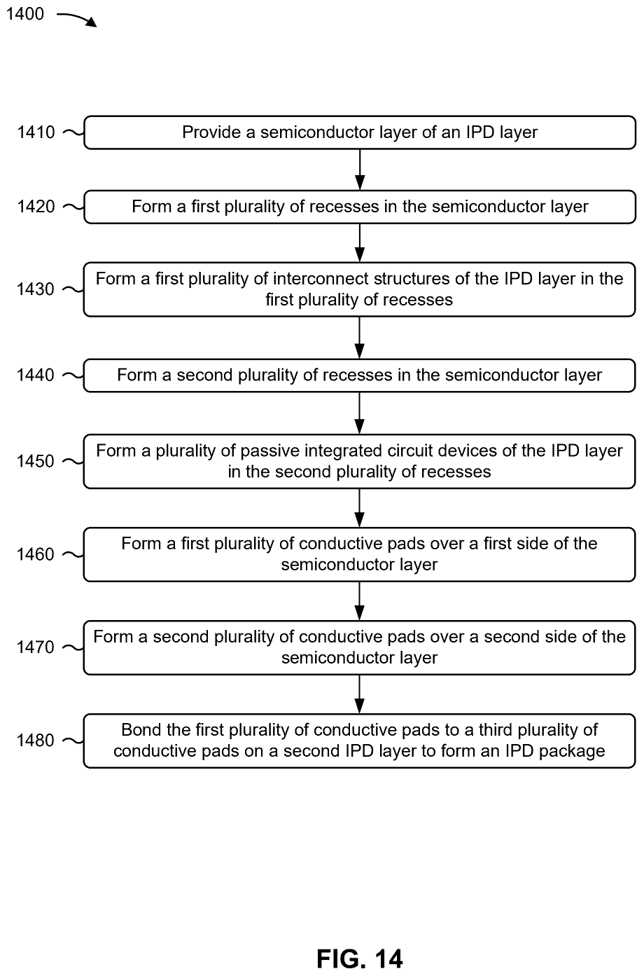

FIG. 14 is a flowchart of an example process 1400 associated with forming an IPD package described herein. In some implementations, one or more process blocks of FIG. 14 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 14, process 1400 may include providing a semiconductor layer of an IPD layer (block 1410). For example, one or more semiconductor processing tools may be used to provide a semiconductor layer (e.g., a substrate layer 404a) of an IPD layer (402a), as described herein.

As further shown in FIG. 14, process 1400 may include forming a first plurality of recesses in the semiconductor layer (block 1420). For example, one or more semiconductor processing tools may be used to form a first plurality of recesses (e.g., recesses 1002) in the semiconductor layer, as described herein.

As further shown in FIG. 14, process 1400 may include forming a first plurality of interconnect structures of the IPD layer in the first plurality of recesses (block 1430). For example, one or more semiconductor processing tools may be used to form a first plurality of interconnect structures (e.g., interconnect structures 410a) of the IPD layer in the first plurality of recesses, as described herein.

As further shown in FIG. 14, process 1400 may include forming a second plurality of recesses in the semiconductor layer (block 1440). For example, one or more semiconductor processing tools may be used to form a second plurality of recesses (e.g., recesses 1004) in the semiconductor layer, as described herein.

As further shown in FIG. 14, process 1400 may include forming a plurality of passive integrated circuit devices of the IPD layer in the second plurality of recesses (block 1450). For example, one or more semiconductor processing tools may be used to form a plurality of passive integrated circuit devices (e.g., passive device structures 318a) of the IPD layer in the second plurality of recesses, as described herein.

As further shown in FIG. 14, process 1400 may include forming a first plurality of conductive pads over a first side of the semiconductor layer (block 1460). For example, one or more semiconductor processing tools may be used to form a first plurality of conductive pads (e.g., conductive pads 406a) over a first side of the semiconductor layer, as described herein.

As further shown in FIG. 14, process 1400 may include forming a second plurality of conductive pads over a second side of the semiconductor layer (block 1470). For example, one or more semiconductor processing tools may be used to form a second plurality of conductive pads (e.g., conductive pads 408a) over a second side of the semiconductor layer, as described herein.

As further shown in FIG. 14, process 1400 may include bonding the first plurality of conductive pads to a third plurality of conductive pads on a second IPD layer to form an IPD package (block 1480). For example, one or more semiconductor processing tools may be used to bond the first plurality of conductive pads (e.g., conductive pads 408a) to a third plurality of conductive pads (e.g., conductive pads 408b) on a second IPD layer (e.g., a second IPD layer 402b) to form an IPD package (e.g., the IPD package 316), as described herein.

Process 1400 may include additional implementations, such as any single implementation or any combination of implementations described below and/or in connection with one or more other processes described elsewhere herein.

In a first implementation, process 1400 includes forming a recess (e.g., a recess 312) in a substrate core (e.g., a substrate core 302) of a package substrate (e.g., a package substrate 102) of a semiconductor package (e.g., a semiconductor package 100), placing the IPD package in the recess, forming a first redistribution structure (e.g., a first redistribution structure 304a) on a first side of the substrate core such that a first side of the IPD package is connected to the first redistribution structure, and forming a second redistribution structure (e.g., a second redistribution structure 304b) on a second side of the substrate core such that a second side of the IPD package is connected to the second redistribution structure.

In a second implementation, alone or in combination with the first implementation, process 1400 includes placing the IPD package on conductive structures (e.g., conductive structures 322a, conductive structures 322b) of a redistribution structure (e.g., the first redistribution structure 304a, the second redistribution structure 304b) of a package substrate (e.g., the package substrate 102) of a semiconductor package (e.g., the semiconductor package 100).

In a third implementation, alone or in combination with one or more of the first and second implementations, forming the first plurality of recesses includes forming the first plurality of recesses in the first side of the semiconductor layer, and forming the second plurality of recesses includes forming the second plurality of recesses in the first side of the semiconductor layer.

In a fourth implementation, alone or in combination with one or more of the first through third implementations, forming the first plurality of recesses includes forming the first plurality of recesses in the first side of the semiconductor layer, and forming the second plurality of recesses includes forming the second plurality of recesses in the second side of the semiconductor layer.

Although FIG. 14 shows example blocks of process 1400, in some implementations, process 1400 includes additional blocks, fewer blocks, different blocks, or differently arranged blocks than those depicted in FIG. 14. Additionally, or alternatively, two or more of the blocks of process 1400 may be performed in parallel.

In this way, an IPD package is manufactured to include electrical connections on two or more sides of the IPD package. For example, an IPD package described herein may include a first plurality of conductive pads on a first side (e.g., a top side) of the IPD package and a second plurality of conductive pads on a second side (e.g., a bottom side) of the IPD package vertically opposing the first side. The IPD package may be embedded in a package core of a package substrate of a semiconductor package, which enables electrical connections to be connected to top and bottom redistribution structures of the package substrate using the conductive pads on the top side and on the bottom side of the IPD package, thereby enabling the quantity and density of passive device structures included in the IPD package to be increased. The electrical connections on two or more sides of the IPD package enable the IPD package to include a plurality of IPD layers or slides of passive device components. The plurality of IPD layers of passive device components may be vertically stacked, and the quantity of IPD layers included in the IPD package may be flexibly selected. Vertically stacking the IPD layers of passive device components enables the quantity and density of passive device structures included in the IPD package to be further increased.

As described in greater detail above, some implementations described herein provide an IPD package. The IPD package includes a first IPD layer and a second IPD layer. The first IPD layer includes a first semiconductor layer and a first plurality of passive device structures in the first semiconductor layer. The second IPD layer includes a second semiconductor layer and a second plurality of passive device structures in the second semiconductor layer. The first IPD layer and the second IPD layer are bonded together such that the first IPD layer and the second IPD layer are vertically stacked in the IPD package.

As described in greater detail above, some implementations described herein provide a semiconductor package. The semiconductor package includes a package substrate. The package substrate includes a substrate core that includes a substrate layer. The package substrate includes a first redistribution structure on a first side of the substrate layer. The package substrate includes a second redistribution structure on a second side of the substrate layer opposing the first side. The first redistribution structure, the substrate core, and the second redistribution structure are stacked and vertically arranged in the semiconductor package. An IPD package is embedded in the substrate core vertically between the first redistribution structure and the second redistribution structure. The IPD package includes first plurality of conductive pads, on a third side of the IPD package, connected to a first plurality of conductive structures in the first redistribution structure. The IPD package includes a second plurality of conductive pads, on a fourth side of the IPD package vertically opposing the third side, connected to a second plurality of conductive structures in the second redistribution structure. The semiconductor package includes a semiconductor die package attached to the package substrate.

As described in greater detail above, some implementations described herein provide a method. The method includes providing a semiconductor layer of an IPD layer. The method includes forming a first plurality of recesses in the semiconductor layer. The method includes forming a first plurality of interconnect structures of the IPD layer in the first plurality of recesses. The method includes forming a second plurality of recesses in the semiconductor layer. The method includes forming a plurality of passive integrated circuit devices of the IPD layer in the second plurality of recesses. The method includes forming a first plurality of conductive pads over a first side of the semiconductor layer. The method includes forming a second plurality of conductive pads over a second side of the semiconductor layer. The method includes bonding the first plurality of conductive pads to a third plurality of conductive pads on a second IPD layer to form an IPD package.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated passive device (IPD) package, comprising:
a first IPD layer, comprising:
a first semiconductor layer; and
a first plurality of passive device structures in the first semiconductor layer; and
a second IPD layer, comprising:
a second semiconductor layer; and
a second plurality of passive device structures in the second semiconductor layer,
wherein the first IPD layer and the second IPD layer are bonded together such that the first IPD layer and the second IPD layer are vertically stacked in the IPD package.

2. The IPD package of claim 1, wherein the first IPD layer further comprises:
a first plurality of conductive pads on a first side of the first semiconductor layer; and
a second plurality of conductive pads on a second side of the first semiconductor layer opposing the first side,
wherein the first plurality of passive device structures are located vertically between the first plurality of conductive pads and the second plurality of conductive pads in the first semiconductor layer.

3. The IPD package of claim 2, wherein the first IPD layer further comprises:
a plurality of interconnect structures that extend through the first semiconductor layer alongside the first plurality of passive device structures.

4. The IPD package of claim 3, wherein the plurality of interconnect structures are coupled to the first plurality of conductive pads at first ends of the plurality of interconnect structures, and
wherein the plurality of interconnect structures are coupled to the second plurality of conductive pads at second ends of the plurality of interconnect structures opposing the first ends.

5. The IPD package of claim 2, wherein the second IPD layer further comprises:
a third plurality of conductive pads on a third side of the second semiconductor layer; and
a fourth plurality of conductive pads on a fourth side of the second semiconductor layer opposing the third side,
wherein the second plurality of passive device structures are located vertically between the third plurality of conductive pads and the fourth plurality of conductive pads in the second semiconductor layer.

6. The IPD package of claim 5, wherein the first plurality of conductive pads of the first IPD layer are bonded to the third plurality of conductive pads of the second IPD layer.

7. The IPD package of claim 6, wherein the first IPD layer further comprises:
a first dielectric layer on the first side of the first semiconductor layer;
wherein the second IPD layer further comprises:
a second dielectric layer on the third side of the first semiconductor layer; and
wherein the first dielectric layer is bonded to the second dielectric layer.

8. The IPD package of claim 2, further comprising:
a plurality of package connection structures attached to the second plurality of conductive pads.

9. A semiconductor package, comprising:
a package substrate, comprising:
a substrate core comprising a substrate layer;
a first redistribution structure on a first side of the substrate layer;
a second redistribution structure on a second side of the substrate layer opposing the first side,
wherein the first redistribution structure, the substrate core, and the second redistribution structure are stacked and vertically arranged in the semiconductor package; and
an integrated passive device (IPD) package embedded in the substrate core vertically between the first redistribution structure and the second redistribution structure,
wherein the IPD package comprises:
first plurality of conductive pads, on a third side of the IPD package, connected to a first plurality of conductive structures in the first redistribution structure; and
second plurality of conductive pads, on a fourth side of the IPD package vertically opposing the third side, connected to a second plurality of conductive structures in the second redistribution structure; and
a semiconductor die package attached to the package substrate.

10. The semiconductor package of claim 9, wherein the IPD package further comprises
a plurality of vertically-arranged layers of passive integrated circuit structures.

11. The semiconductor package of claim 10, wherein a first layer of passive integrated circuit structures, of the plurality of vertically-arranged layers of passive integrated circuit structures, is connected to the first plurality of conductive pads; and
wherein a second layer of passive integrated circuit structures, of the plurality of vertically-arranged layers of passive integrated circuit structures, is connected to the second plurality of conductive pads.

12. The semiconductor package of claim 10, wherein the IPD package further comprises:
a third plurality of conductive pads vertically between the first plurality of conductive pads and the second plurality of conductive pads; and
a fourth plurality of conductive pads vertically between the second plurality of conductive pads and the third plurality of conductive pads.

13. The semiconductor package of claim 12, wherein a first layer of passive integrated circuit structures, of the plurality of vertically-arranged layers of passive integrated circuit structures, is connected to the first plurality of conductive pads; and
wherein a second layer of passive integrated circuit structures, of the plurality of vertically-arranged layers of passive integrated circuit structures, is connected to the third plurality of conductive pads.

14. The semiconductor package of claim 12, wherein a first layer of passive integrated circuit structures, of the plurality of vertically-arranged layers of passive integrated circuit structures, is connected to the third plurality of conductive pads; and
wherein a second layer of passive integrated circuit structures, of the plurality of vertically-arranged layers of passive integrated circuit structures, is connected to the fourth plurality of conductive pads.

15. The semiconductor package of claim 12, wherein the IPD package further comprises:
a first plurality of interconnect structures extending between the first plurality of conductive pads and the third plurality of conductive pads; and
a second plurality of interconnect structures extending between the second plurality of conductive pads and fourth plurality of conductive pads.

16. A method, comprising:
providing a semiconductor layer of an integrated passive device (IPD) layer;
forming a first plurality of recesses in the semiconductor layer;
forming a first plurality of interconnect structures of the IPD layer in the first plurality of recesses;
forming a second plurality of recesses in the semiconductor layer;
forming a plurality of passive integrated circuit devices of the IPD layer in the second plurality of recesses;
forming a first plurality of conductive pads over a first side of the semiconductor layer;
forming a second plurality of conductive pads over a second side of the semiconductor layer; and
bonding the first plurality of conductive pads to a third plurality of conductive pads on a second IPD layer to form an IPD package.

17. The method of claim 16, further comprising:
forming a recess in a substrate core of a package substrate of a semiconductor package;
placing the IPD package in the recess;
forming a first redistribution structure on a first side of the substrate core such that a first side of the IPD package is connected to the first redistribution structure; and
forming a second redistribution structure on a second side of the substrate core such that a second side of the IPD package is connected to the second redistribution structure.

18. The method of claim 16, further comprising:
placing the IPD package on conductive structures of a redistribution structure of a package substrate of a semiconductor package.

19. The method of claim 16, wherein forming the first plurality of recesses comprises:
forming the first plurality of recesses in the first side of the semiconductor layer; and
wherein forming the second plurality of recesses comprises:
forming the second plurality of recesses in the first side of the semiconductor layer.

20. The method of claim 16, wherein forming the first plurality of recesses comprises:
forming the first plurality of recesses in the first side of the semiconductor layer; and
wherein forming the second plurality of recesses comprises:
forming the second plurality of recesses in the second side of the semiconductor layer.
